(19) United States
(12) Patent Application Publication
(10) Pub. No.: US 2025/0371204 A1
(43) Pub. Date: Dec. 4, 2025

(54) SYSTEMS AND METHODS FOR A DEMONSTRATIVE MODEL WITH SELECTABLE SPACE

(71) Applicants: John Dickerson LUGAR, Roanoke, VA (US); Henry D. Lugar, Roanoke, VA (US)

(72) Inventors: John Dickerson LUGAR, Roanoke, VA (US); Henry D. Lugar, Roanoke, VA (US)

(21) Appl. No.: 18/676,155

(22) Filed: May 28, 2024

(51) Int. Cl. G06F 30/13; E04B 1/343

(52) U.S. Cl. CPC G06F 30/13; E04B 1/343

(57) ABSTRACT

A storage facility with a plurality of different unit sizes includes a demonstrative model to aid in the presentation of the different sizes to a potential customer. The available unit sizes each have a common nominal dimension; the demonstrative model includes a rectangular boundary sharing the common dimension. The model includes a plurality of vertically extending walls, a floor and a selectable wall that also shares the common nominal dimension. The selectable wall extends between first and second walls and the selectable wall is locatable at a plurality of predefined positions, such that each predefined position reflects the non-common dimension of a respective one of the plurality of the different unit sizes. The selectable wall is preferably biased to each of the predefined positions, such that each of the available sizes may be easily demonstrated to the customer by moving the selectable wall and without the need to separately visit each of the available sizes at different locations at the facility.

### CROSS REFERENCE TO RELATED APPLICATIONS

This application claims priority to the concurrently filed application of Lugar et. al. titled “SYSTEMS AND METHODS FOR A DEMONSTRATIVE MODEL WITH SELECTABLE SPACE” filed on May 28, 2024. This application claims the benefit of priority under 35 U.S.C. § 119(e) to prior U.S. Provisional Application No. 63/544,503 filed on Oct. 17, 2023, the disclosures of the provisional application as well as the concurrently filed application are incorporated by reference herein in their entirety.

### FIELD OF DISCLOSURE

The disclosed system and method relate to demonstrative model systems configured to adjust a size of a space to a plurality of different sizes.

### BACKGROUND

Storage facilities provide customers with a variety of different storage space sizes, giving the customers options based on their storage needs. Conventionally, the storage facility manager has to show customers empty storage units of varying sizes before the customer may decide on a storage space size. This process may be time consuming for the customer and the manager. It also does not let the customer compare the storage unit sizes in real time. To save time, some storage facilities provide customers with a painted representation of each size storage unit in one big room or just give examples of what you may fit in each size unit. These processes, while marginally useful, do not allow the customer to visualize the storage size space effectively, and the customer could end up deciding on a space that is too large or too small, detrimentally effecting the customer's experience with the operator. It is envisioned that one solution would be to provide a full size model of each storage unit, offered by facility, within the Office or showroom. However, such a solution has practical and economic disadvantages. First, the showroom or office would require the space to display each unit size which increases building cost. In a facility offering 10×5, 10×10, 10×15, 10×20, 10×25 and 10×30 (generally the industry standard sizes), the additional square feet required would be 1050 square feet (f²), which would be 750 f² more than the solutions presented below which could increase the cost of the facility by well over $150,000 (2024 dollars). Secondly, the space may not be available, or practical in already existing facilities, and lastly, the opportunity cost in allowing that square footage to remain fallow may also exceed $150,000, and even more in high cost regions.

Accordingly, there has been a long felt need to simplify the storage unit rental decision making process. The present disclosure addresses the shortcomings of conventional storage facility processes and allows the customer to make a quicker, well informed decision regarding the storage unit size to rent.

### SUMMARY OF THE DISCLOSURE

The embodiments described herein are directed to apparatuses, systems and methods for demonstrating storage spaces to prospective customers. In addition to or instead of the advantages presented herein, persons of ordinary skill in the art would recognize and appreciate other advantages as well.

It is an object of the present disclosures to present a novel system which includes, at least one track coupled to a portion of a partially enclosed space and a movement mechanism associated with t track; a barrier is operatively coupled to the movement mechanism, such that the barrier may move along the at least one track to each of a plurality of predefined positons. In the system, the barrier is biased to each of the plurality of predefined positions and further includes a display which shows a storage unit size corresponding to a respective one of the plurality of predefined positions.

It is also an object of the present disclosure to present a novel storage facility including a plurality of available unit sizes, with one nominal dimension in common. The storage facility including a demonstrative model system for representing the available unit sizes. The demonstrative model system having a rectangular boundary, with one side being the common dimension and a plurality of walls extending vertically from the rectangular boundary, a floor perpendicular to and continuous within the rectangular boundary; and at least one selectable wall having the common dimension. The selectable wall of the demonstrative model system extends between at least one of the walls and a second side of the rectangular boundary disposed opposite of the wall and wherein the selectable wall is locatable at a plurality of predefined positions, such that each position reflects the non common dimension of a respective one of the plurality of available unit sizes.

It is another object of the present disclosure to present a novel demonstrative model system, the system including a first, second and third wall, where the first and second walls are parallel and the third wall is perpendicular to them. The system further includes a fourth wall extending between the first and second walls, positional along the first wall and the second wall with respect to the third wall. The walls defining a selectable space based on one of a plurality of positions of the fourth wall with respect to the third wall, where the fourth wall is suspended from overhead, supported by a floor or by the first or second walls. The selectable space and the respective positions of the fourth wall are predetermined; and, the fourth wall is biased to each of the plurality of positions.

It is still another object of the present disclosures to present a novel method for dividing a space. The method including providing a horizontal space with a plurality of key measurement intervals reflective of a plurality of predefined spaces; providing a demonstrative model, where the demonstrative model includes at least two fixed vertical walls and a moveable barrier; the at least two fixed walls defining at least two boundary lines of the space and the moveable barrier extending vertically from the horizontal space. The method further including moving the moveable barrier within the space to one of the plurality of key measurement intervals; where the moveable barrier and the fixed walls define three sides of one of the plurality of predefined spaces reflected by the respective key measurement interval. The method then includes moving the moveable barrier within the horizontal space to a second of the plurality of key measurement intervals, wherein the moveable barrier and the two fixed walls define three sides of another of the plurality of predefines spaces reflected by the second key measurement interval; and providing an indicia for each of the plurality of key measurement intervals, the indicia reflective of a size of the respective ones of the plurality of predefined spaces, where the indicia is permanent or transient.

It is yet another object of the present disclosures to present a novel demonstrative variable area storage unit. The storage unit including a wall and a first plane parallel to and oriented opposite the wall, the wall and the first plane spaced apart by a predetermined common value and defining a longitudinal passage, the longitudinal passage between the wall and first plane defining a first area and a plurality of predetermined locations located along the longitudinal passage each of the predetermined locations associated with at least one of a plurality of predetermined layouts. The storage unit further including a plurality of deployable barriers, each of the deployable barrier located at a respective one of the plurality of predetermined locations and each of the deployable barrier having a deployed position and a retracted position; in the deployed position, each of the deployable barriers along with the wall and first plane enclose a respective one of a plurality of predefined layouts, wherein each of the plurality of predefined areas are less that the first area; and, the plurality of predefined layouts represent available storage units.

It is an additional object of the present disclosure to present a novel method of demonstrating a plurality of storage unit sizes, wherein each of the plurality of storage units have a respective length and share a common width. The method including obtaining the respective length dimensions for each of the plurality of storage units and providing a rectangular area, the rectangular area having a first dimension greater than or equal to each of the respective length dimensions and a common width dimension. The method includes selectively dividing the rectangular area to represent at least one of a set of rectangles, each sharing at least the common width dimension corresponding in size with a respective one of the plurality of storage unit sizes and moving a barrier to each of the different length dimensions represented in the set of rectangles to demonstrate the respective storage unit size.

It is still an additional object of the present disclosure to present a novel movable wall. The wall including at least one surface representative of a space; a support mechanism configured to movably position the movable wall horizontally with respect to its proximate environment; and a plurality of stops interacting with the proximate environment to bias the movable wall at each of a plurality of predetermined positions, wherein each of the plurality of predetermined positions comprise an indicia viewable by an operation, the indicia reflective of a representative size of the space associated with the respective predetermined positions, and wherein the indicia is permanent or transient.

It is yet an additional object of the present disclosure to present a novel method of demonstrating a plurality of different sized storage units to a customer with a demonstrator unit where the demonstrator unit includes several deployable walls prepositioned within a rectangular space, such that their deployment configurations are reflective of different sized storage units. The method including receiving input from the customer at the computer; collecting, vacancy information regarding available storage unit sizes and comparing the customer input and vacancy information to devise a set of conforming unit sizes, and, generating control signals by the computer reflective of the set of unit sizes. The method further includes deploying respective ones of the deployable walls within the rectangular space according to one or more predetermined configurations to reflect the available storage unit sizes in response to the control signals; and, receiving from the customer a selection of one of the predetermined configurations and identifying to the customer one or more storage units reflective of the selection.

These and many other objects and advantages of the disclosed subject matter will be readily apparent to one skilled in the art to which the subject matter pertains from a perusal of the claims, the appended drawings, and the following detailed description of preferred embodiments.

### BRIEF DESCRIPTION OF THE DRAWINGS

The features and advantages of the present disclosure will be more fully disclosed in, or rendered obvious by, the following detailed descriptions of example embodiments. The detailed descriptions of the example embodiments are to be considered together with the accompanying drawings wherein like numbers refer to like parts and further wherein:

FIG. 1A illustrates a demonstrative model system in accordance with some embodiments;

FIG. 1B illustrates a storage facility having a first example of a demonstrative model system in accordance with some embodiments;

FIG. 2 illustrates track and a barrier connection of a demonstrative model system in accordance with some embodiments;

FIG. 3A illustrates another track and a barrier connection of a demonstrative model system in accordance with some embodiments;

FIG. 3B illustrates various biasing devices a demonstrative model system in accordance with some embodiments

FIG. 3C illustrates example indentation types of a demonstrative model system in accordance with some embodiments;

FIG. 4 illustrates an embodiment of a demonstrative model system with a movable barrier demonstrating plural unit sizes;

FIG. 5 illustrates a demonstrative model with a door in accordance with some embodiments;

FIG. 6A illustrates an isometric view of a variation of a demonstrative model system in accordance with some embodiments;

FIG. 6B illustrates an isometric view of another variation of a demonstrative model system in accordance with some embodiments;

FIG. 6C illustrates an isometric view of an additional variation of a demonstrative model system in accordance with some embodiments;

FIG. 6D illustrates a top down view of a pair of tracks of a demonstrative model system in accordance with some embodiments;

FIG. 6E illustrates a movement mechanism of a demonstrative model system in accordance with some embodiments;

FIG. 6F illustrates a brace of a demonstrative model system in accordance with some embodiments;

FIG. 6G illustrates a storage facility including a demonstrative model system in accordance with some embodiments;

FIG. 7A-7C illustrates an isometric view of yet another variation of a demonstrative model system in accordance with some embodiments;

FIG. 7D illustrates an isometric view of still another variation of a demonstrative model system in accordance with some embodiments;

FIG. 7E illustrates an isometric view of yet another variation of a demonstrative model system in accordance with some embodiments;

FIG. 8 illustrates an isometric view of yet an additional variation of a demonstrative model system in accordance with some embodiments;

FIG. 9 illustrates a block diagram of an exemplary computing device of a demonstrative model system in accordance with some embodiments;

FIG. 10A illustrates a first orientation of a demonstrative model system in accordance with some embodiments;

FIG. 10B illustrates a second orientation of a demonstrative model system in accordance with some embodiments;

FIGS. 11A-11E illustrates variation in barrier/wall types for a demonstrative model system in accordance with some embodiments;

FIG. 12 illustrates a further variation of a demonstrative model system in accordance with some embodiments; and,

FIG. 13 illustrates a flowchart of an exemplary method of a demonstrative model system in accordance with some embodiments.

FIG. 14 illustrates an automated system for demonstrating the available storage unit sizes in accordance with some embodiments.

While the disclosed subject matter is susceptible to various modifications and alternative forms, specific embodiments have been shown by way of example in the drawings and will be described in detail herein. It should be understood however, that the present disclosure is not intended to be limited to the particular forms disclosed. Rather, the present disclosure is to cover all modifications, equivalents, and alternatives falling within the spirit and scope of the disclosure as defined by the appended claims.

### DETAILED DESCRIPTION

This description of the exemplary embodiments is intended to be read in connection with the accompanying drawings, which are to be considered part of the entire written description. It should be understood, however, that the present disclosure is not intended to be limited to the particular forms disclosed and that the drawings are not necessarily shown to scale. Rather, the present disclosure covers all modifications, equivalents, and alternatives that fall within the spirit and scope of these exemplary embodiments. In the description, relative terms such as “lower,” “upper,” “horizontal,” “vertical,” “above,” “below,” “up,” “down,” “top,” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. The terms “couple,” “coupled,” “operatively coupled,” “operatively connected,” and the like should be broadly understood to refer to connecting devices or components together either mechanically, or otherwise, such that the connection allows the pertinent devices or components to operate with each other as intended by virtue of that relationship.

The devices, systems, and methods being disclosed enable a prospective storage unit customer to quickly and effectively decide which size storage unit to rent. The demonstrative model systems of the present disclosure allow for quick and effective space size representations, enabling a customer to make quick, informed, and precise storage unit size decisions based on their storage needs. Likewise, the use of the devices, systems and methods described herein advantageously allow the operator to effectively and efficiently aid the prospective customer in selecting an appropriate storage unit size. The demonstration model represents a cost efficient manner for improving customer experience resulting in increased rentals, better rates, longer terms and thus greater revenue.

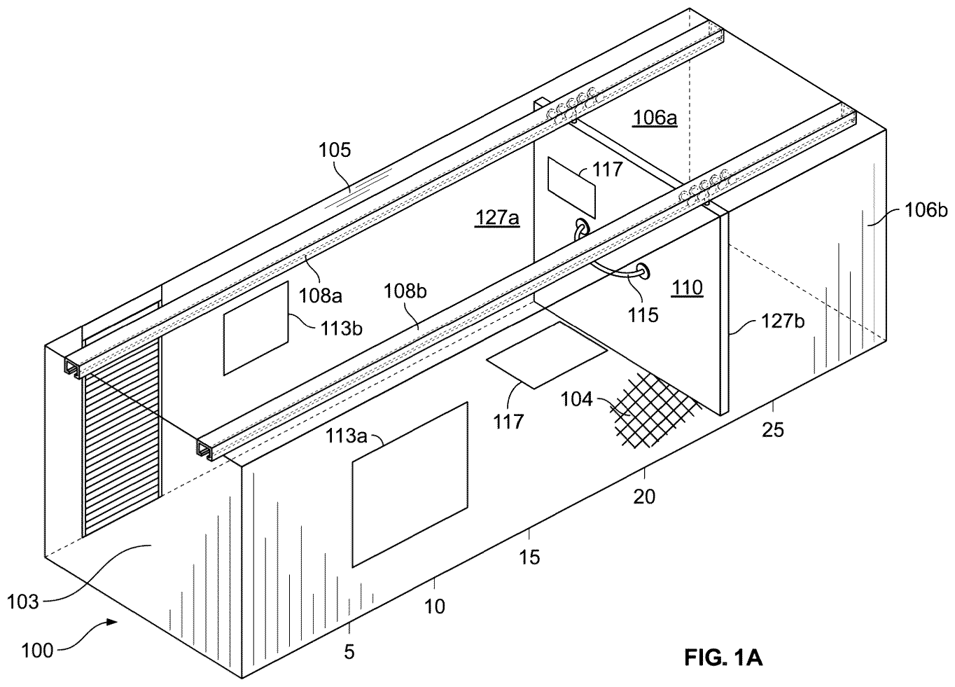

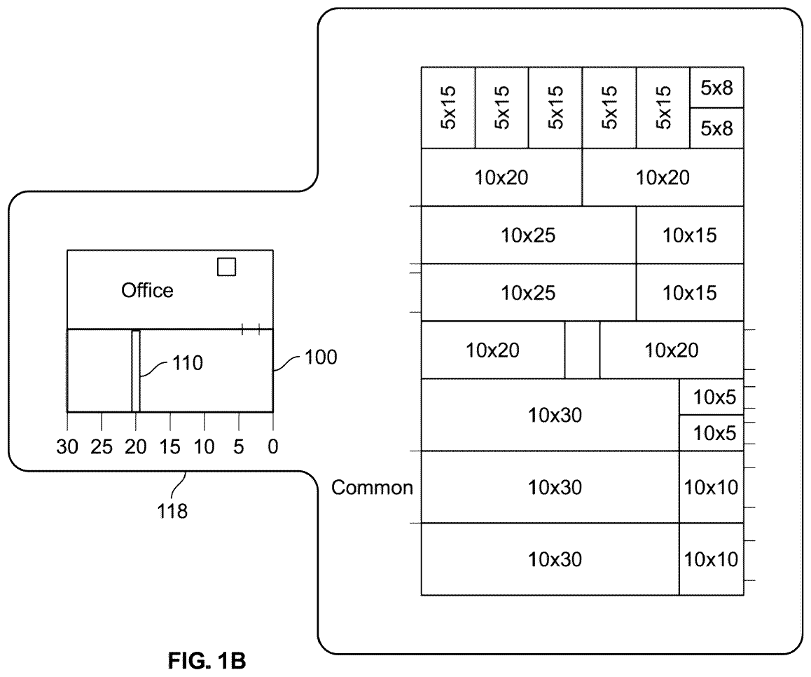

FIG. 1A illustrates a demonstrative model system 100 in accordance with some embodiments. The demonstrative model system 100 is configured to operate in a space 103. The space 103 may be defined by one or more structures, such as a floor 104, a ceiling 105, at least one wall 106a-b, and at least one barrier 110. The demonstrative model system 100 may include at least one track 108a-b coupled to a portion of the space 103 and the at least one barrier 110.

The space 103 may be any suitable volume, such as a room or storage unit. The space 103 may be fully enclosed with the floor 104, the ceiling 105, the walls 106a-b, the barrier 110, and one or more end walls similar to a regular storage unit. For example, the floor 104 may be concrete and the walls 106a-b are made of metal, such as aluminum or metal alloy, so as to simulate the feel of a storage unit. In other embodiments, the floor 104 may include other materials such as epoxy, paint, or made of wood just to provide a few examples. The space 103 may also have one or more windows 113a-b disposed within the walls 106a-b so a customer may see the demonstrative model system 100 from outside of the space 103, and presents an open feeling when the customer is within the space.

In some embodiments, the demonstrative model system 100 includes two tracks 108a-b to provide better stability. In even further embodiments, the demonstrative model system 100 may include one or more tracks on the wall 106a-b of the space 103 and/or on the floor 104 of the space 103 in addition to or in place of the tracks 108a-b as illustrated in FIG. 1A. Although two tracks 108a-b are shown, it will be appreciated that the demonstrative model system 100 may include more or less tracks.

As illustrated in FIG. 1A, the barrier 110 is configured to move along the tracks 108a-b. In some embodiments, the barrier 110 may include a handle 115 for an operator user (e.g., the storage facility manager or the customer) to push or pull the barrier 110 along the tracks 108a-b to change the position of the barrier 110. A user of the demonstrative model system 100 may stop the barrier 110 at key measurement intervals corresponding to different storage space sizes. For example, the barrier 110 may be stopped at positions corresponding to a 5 feet by 10 feet, 10 feet by 10 feet, 10 feet by 15 feet, 10 feet by 20 feet, 10 feet by 25 feet, 10 feet by 30 feet, 10 feet by 35 feet, 10 feet by 40 feet, or some other size corresponding to a storage unit size associated with the particular storage facility. The particular nominal sizes described herein are for ease of describing the disclosed subject matter and not intended to limit the disclosure as other nominal sizes are also envisioned. As described later, the barrier 110 may also be formed of several deployable barriers, each at a fixed position corresponding to one of a plurality of pre-established location, and selectively deployable.

The barrier 110 may be a door, partition, wall, sign, curtain, etc. to simulate a far wall of a storage unit. In some embodiments, the barrier 110 may be of a material substantially similar to a storage unit (e.g., metal, such as aluminum, or metal alloy). However, it will be appreciated that the barrier 110 may be of other materials such as plastic, tarp, drywall, wood or wood composite, fabric, glass, etc. In some embodiments, the barrier 110 may be in the form a light projection (e.g., illuminated screen, hologram, etc.).

The demonstrative model system 100 may include one or more indicia that represent the different storage unit sizes. For example, the indicia may be one or more signs fixed to one of the walls 106a-b, on the floor 104, or hanging from the ceiling 105. The signs may be made of any suitable material such as paper, vinyl, plastic, metal, wood, etc. The indicia may also be presented on a display 117 fixed to a portion of the space 103. For example, the display 117 may be hung from the ceiling 105 or fixed to one of the walls 106a-b. In some embodiments, the display 117 may be fixed to the barrier 110 or disposed within a portion of the barrier 110. In some embodiments, the indicia may be projected onto the barrier 110, the floor 104, or one of the walls 106a-b to indicate the key measurement intervals.

In some embodiments, the demonstrative model system 100 may also include an audio announcement of key measurement intervals when the barrier 110 arrives at a key measurement interval. For example, one or more sensors disposed within the tracks 108a-b, the walls 106a-b, the floor 104, or the ceiling 105 may trigger the projection, display or audible announcement of the respective key measurement interval.

FIG. 1A further illustrates the sides of the barrier 110 of a demonstrative model system 100 in accordance with some embodiments. In some embodiments, the size of the barrier 110 is substantially the same size as the space 103. For example, the barrier 110 may only have an one inch or less gap between the side walls 106a-b and floor 104 of the space 103 to better portray the actual size of a space 103. In some embodiments, the barrier 110 may include guards 127a-b along the edges of the barrier 110 so that the side walls 106a-b and floor 104 are protected from scraping, scratching, rubbing, etc. as the barrier is moved along the at least one track. The guards 127a-b may be made of rubber, plastic, silicone, or some other suitable material.

As illustrated in FIG. 1B, the demonstrative model system 100 may be installed at a storage facility 118. An operator at the storage facility 118 may use the demonstrative model system 100 to easily show a prospective customer the different storage sizes available at the storage facility 118. As discussed above, the demonstrative model system 100 may include one or more windows so that a customer may see the different storage unit sizes through the windows from outside of the space 103.

As shown in FIG. 1B, the operator may be informed of, not only the available units, but the size of units that are vacant, so as to not unnecessarily demonstrate a unit size that is not available to rent. The demonstrative unit 100 may be within the office of the facility 118. The facility, as illustrated may include multiple unit sizes, including 5×10, 5×15, 10×10, 10×15, 10×20, 10×25 and 10×30 units. The office may keep track of the units that are vacant. For example if all of the 10×30 units are rented, the office sales person would not need to demonstrate the 10×30 unit with the demonstrator model system, and in some automated embodiments, the unavailable unit sizes may be blocked from demonstration.

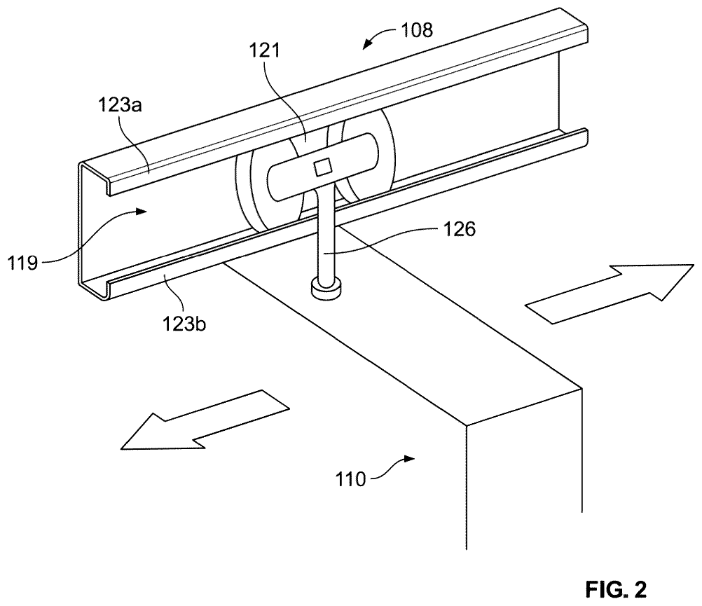

FIG. 2 illustrates a track 108 of a first example of a demonstrative model system 100 in accordance with some embodiments. The track 108 defines a void 119 configured to receive a movement mechanism 121, such as a wheel, bearing, roller, etc. The track 108 also defines a pair of ledges 123a-b configured to fixate the movement mechanism 121 within the void 119 while also allowing the movement mechanism 121 to freely move longitudinally along the track 108. The movement mechanism 121 may be coupled to a first end of a fastener 126, such as a pin or some other suitable fastener. The fastener 126 may also be connected to the barrier 110 at a second end of the fastener 126.

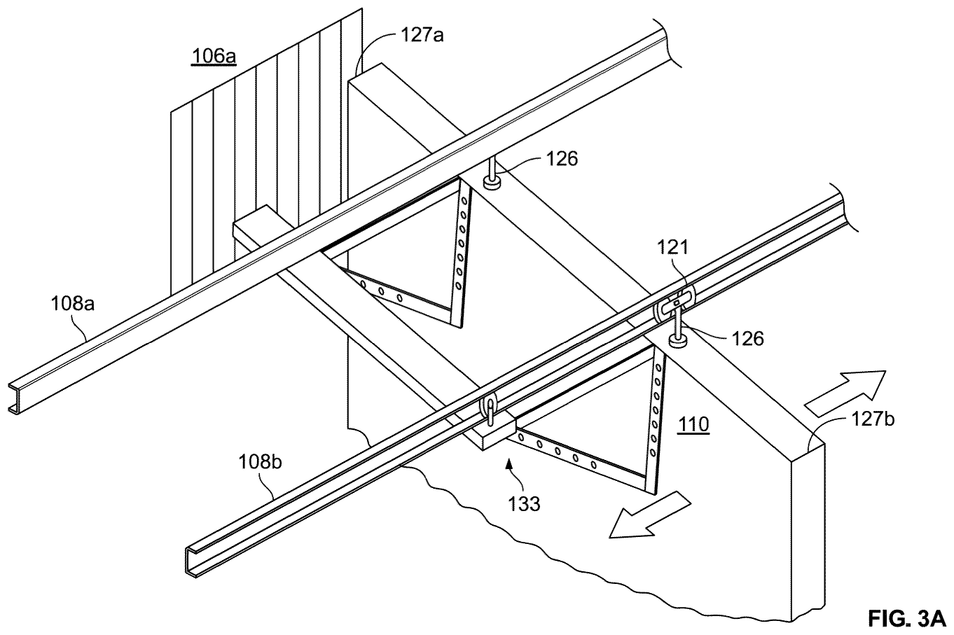

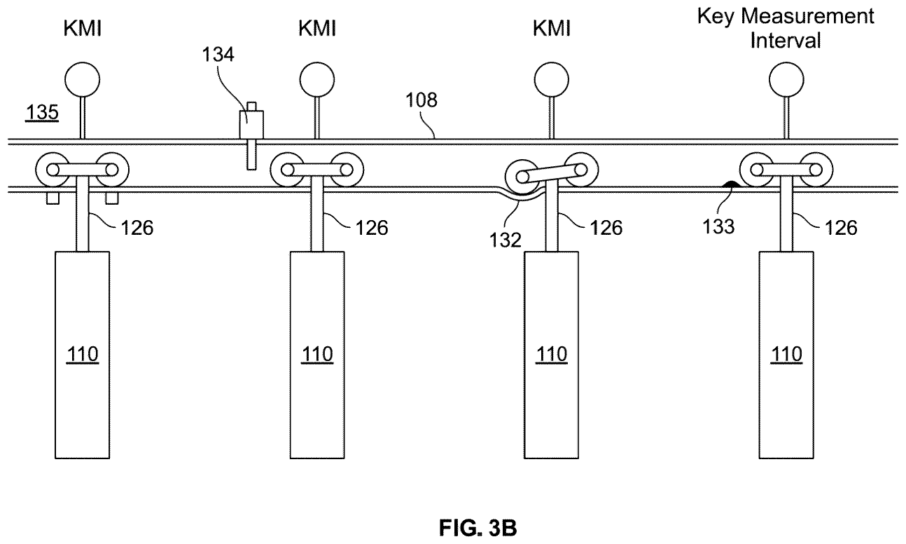

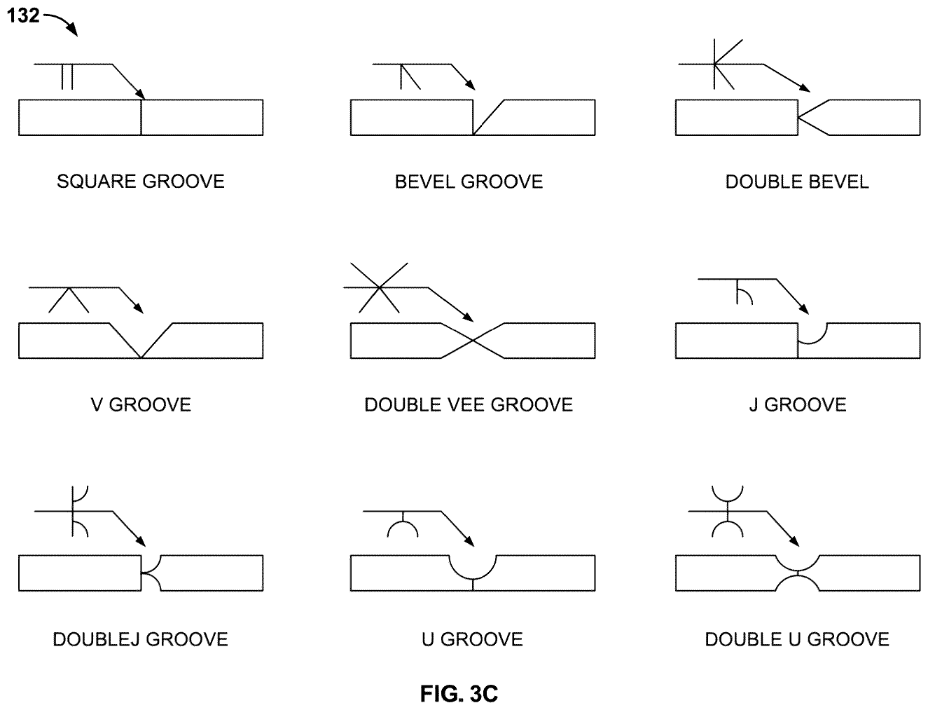

In some embodiments, the demonstrative model system 100 includes a stability mechanism 133 as illustrated in FIG. 3A. The stability mechanism 133 may include one or more brackets coupled to the barrier 110 and/or track 108 so that movement of the barrier 110 is limited, preventing the barrier 110 from swinging laterally (i.e., swinging from a perpendicular position with respect to the floor 104). In some embodiments, the fastener 126 is fixedly coupled to the movement mechanism 121 and barrier 110 so that the fastener 126 is fixed perpendicular to the movement mechanism 121 and barrier 110. In other embodiments, the fastener 126 is flexibly coupled so that the fastener 126 has up to 90 degrees range of motion in the longitudinal direction (i.e., along the direction of the track 108a).

As shown in FIG. 3B, the tracks 108a-b may include indentions 132 or protrusions so that the barrier 110 stops, at least intermittently, at each desired key measurement interval, or is biased to the key measurement intervals. For example, as the barrier 110 is moved from a first position (e.g., 10 feet by 30 feet) to a second position (e.g., 10 feet by 25 feet), the movement of barrier 110 is interrupted by the indention 132 within the tracks 108a-b at the second position, to assist the operator in positioning the barrier 110. When the operator of the demonstrative model system 100 is ready to move the barrier 110 to a third position (e.g., 10 feet by 20 feet) or back to the first position, the operator releases the barrier 110 with a latch or by applying pressure to the barrier to free the barrier 110 from the indention 132. As illustrated in FIG. 3C, the indentations 132 may be one of a square groove, a bevel groove, a double bevel groove, a “V” groove, a double “V” groove, a “J” groove, a double “J” groove, a “U” groove, a double “U” groove, any combination thereof, or some other suitable indentation shape.

It is envisioned that in addition to the protrusion and groove stops, active stops such as actuators 134, transducers, magnetic brakes 135, etc. and other types passive stops known to those having ordinary skill in the art would find advantage in the applications described herein as shown in FIG. 3B.

In further embodiments, magnets may be used to restrain the barrier 110 at each of the key measurement intervals. For example, one or more magnets within the tracks 108a-b may be used to magnetically couple to one or more magnets on to the barrier 110 at each of the plurality of key measurement intervals. To move the barrier 110, the operator of the demonstrative model system 100 applies pressure to the barrier 110 so that the magnets within the tracks 108a-b and the on the barrier 110 are no longer aligned. Magnets could also be implemented on the floor of the space 103 and configured to couple to magnets on the bottom of the barrier 110. Magnets could further be implemented on the walls 106a-b of the space and configured to couple to magnets on the sides of the barrier 110.

In some embodiments, the barrier 110 may be configured for magnetic levitation facilitated by one or more magnets. For example, demonstrative model system 100 may include one or more magnets attached to the barrier 110 and one or more magnets disposed within the tracks 108a-b. The magnets on the barrier 110 may be oriented such that the poles of the magnets align with like poles of the magnets disposed within the tracks 108a-b, resulting in the barrier 110 appearing to levitate off of the floor 104 or from the ceiling 105.

In some embodiments, the demonstrative model system 100 may be configured for magnetic propulsion of the barrier 110 along the tracks 108a-b. The magnetic propulsion may be facilitated by a plurality of magnets disposed on the barrier 110 and within the tracks 108a-b. For example, one or more magnets disposed on the barrier 110 are aligned with magnets disposed within the tracks 108a-b. The like poles of the magnets on the barrier 110 and disposed within the tracks 108a-b push the barrier 110 forward or backward due to the repel force of the like poles. The opposite poles of the magnets on the barrier 110 and disposed within the tracks 108a-b attract, pulling the barrier 110 forward or backward. The repel, or push, force and the pulling forces created by the magnets may cause the barrier 110 to move along the tracks 108a-b.

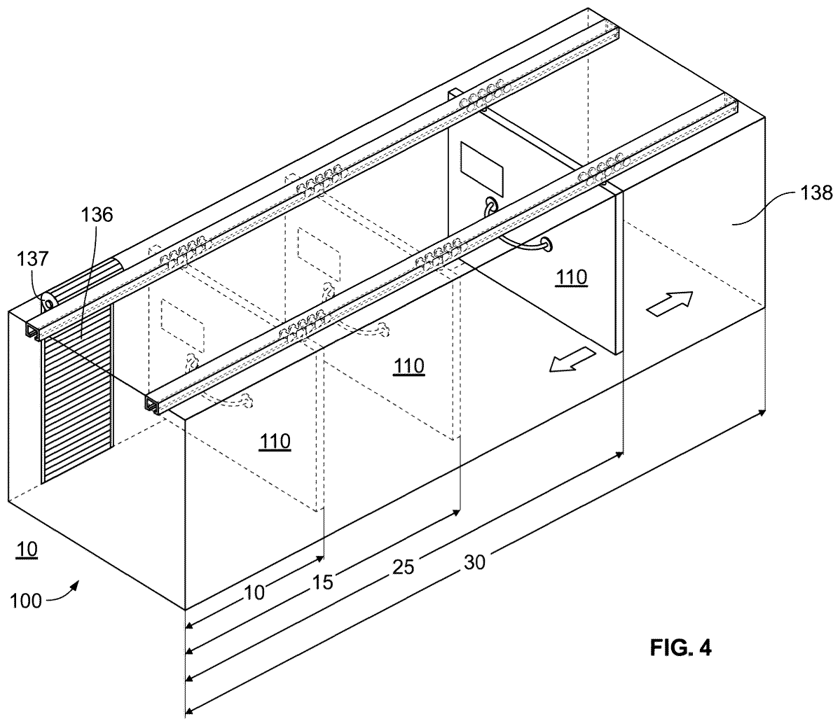

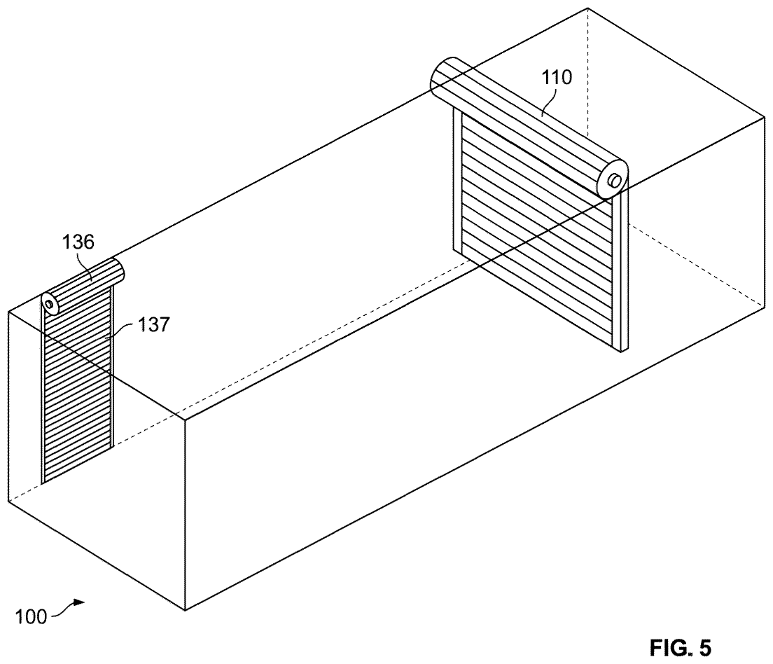

FIG. 5 illustrates an entrance 136 to a space 103 of a first example of a demonstrative model system 100 in accordance with some embodiments. The entrance 136 may include a door 137, such the roll up door illustrated in FIG. 5, so that an operator may teach a customer how to lock/unlock, latch/unlatch, and roll up/down the door 135 to a storage unit. As illustrated in FIG. 4, once the door 137 is open, an operator may show the customer a plurality of different storage unit sizes using the barrier 110 of the demonstrative model system 100 as described above. FIG. 4 illustrates the position of the barrier 110 when demonstrating the key measurement intervals corresponding to 10×10, 10×15, 10×20 (not shown), 10×25 and 10×30 unit sizes. Although the barrier 110 is used to demonstrate the different size storage units, the back wall 138 of the space 103 may also be configured to move similar to barrier 110.

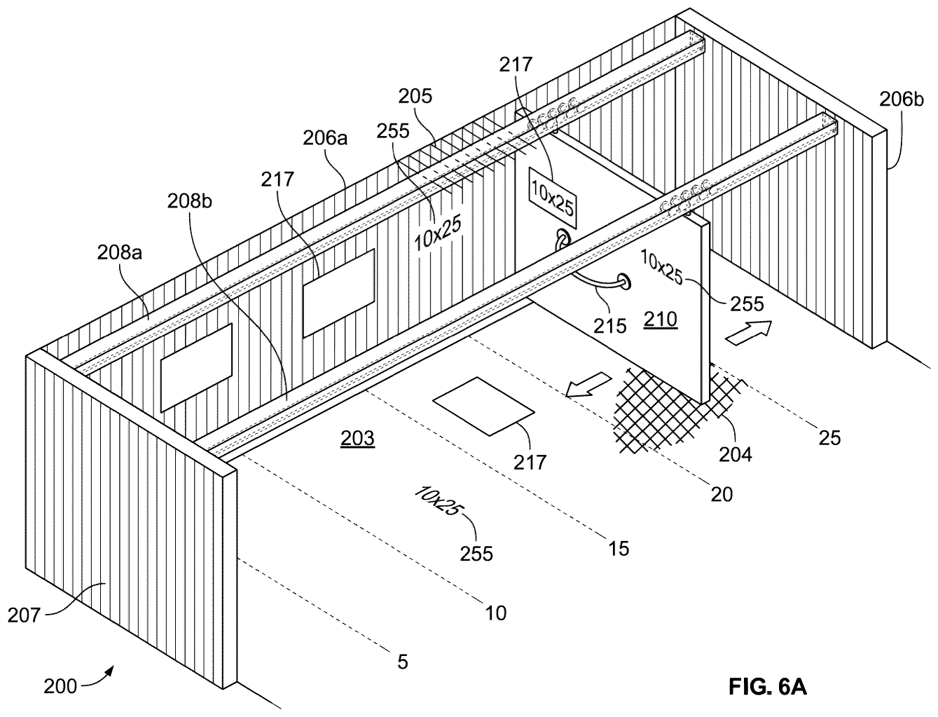

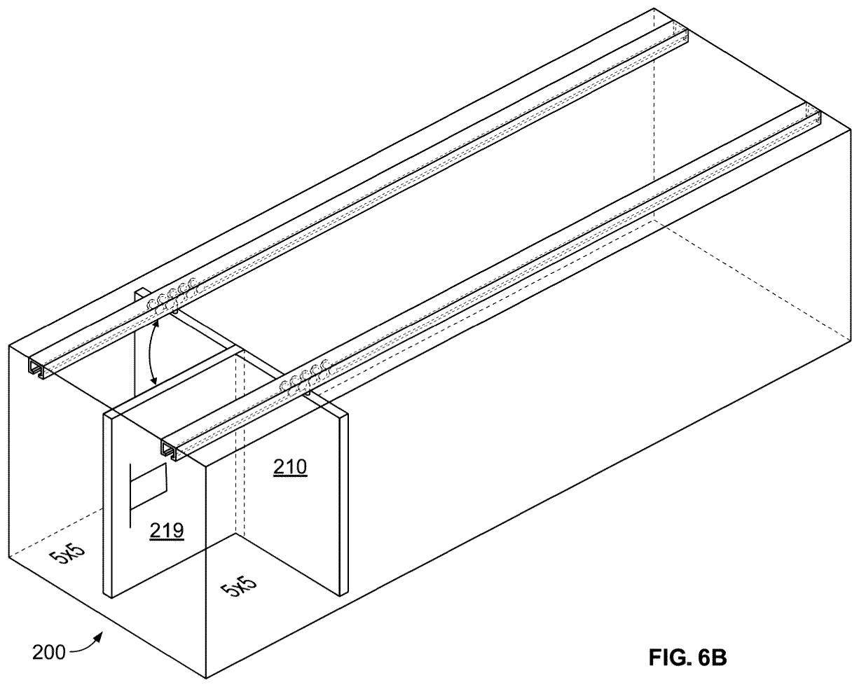

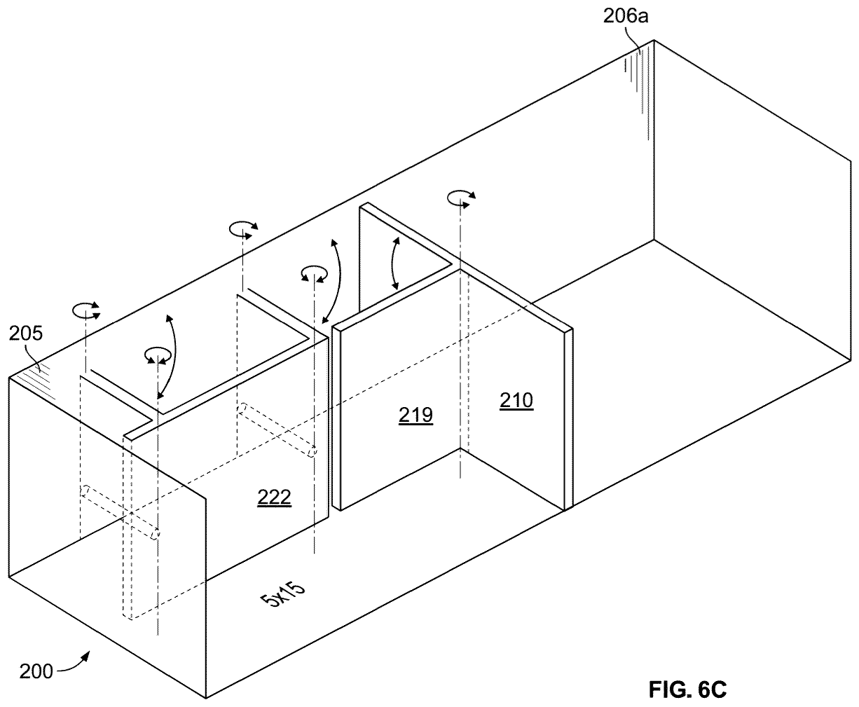

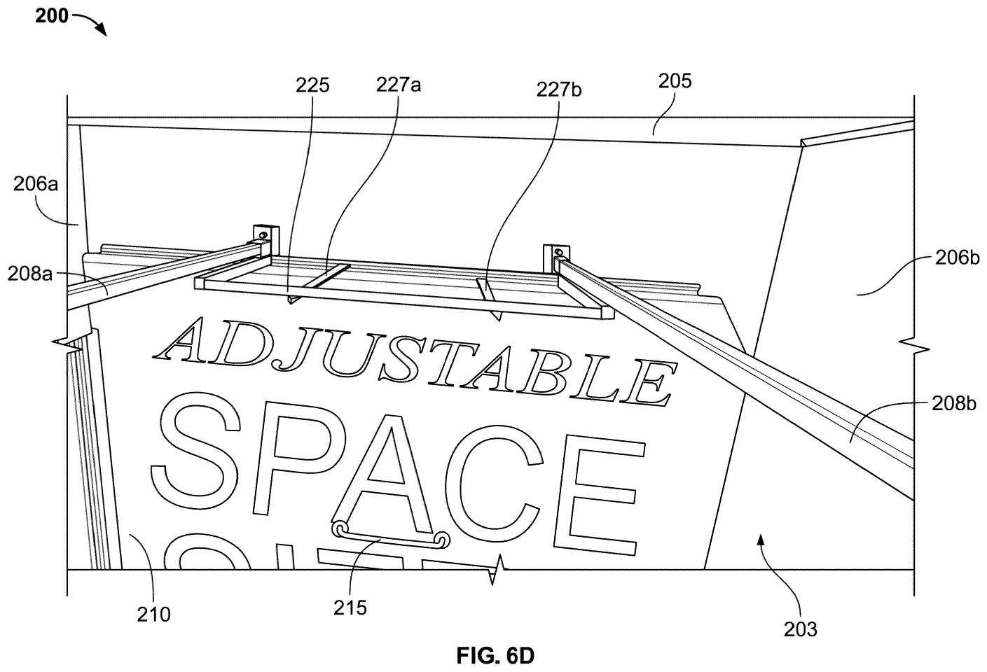

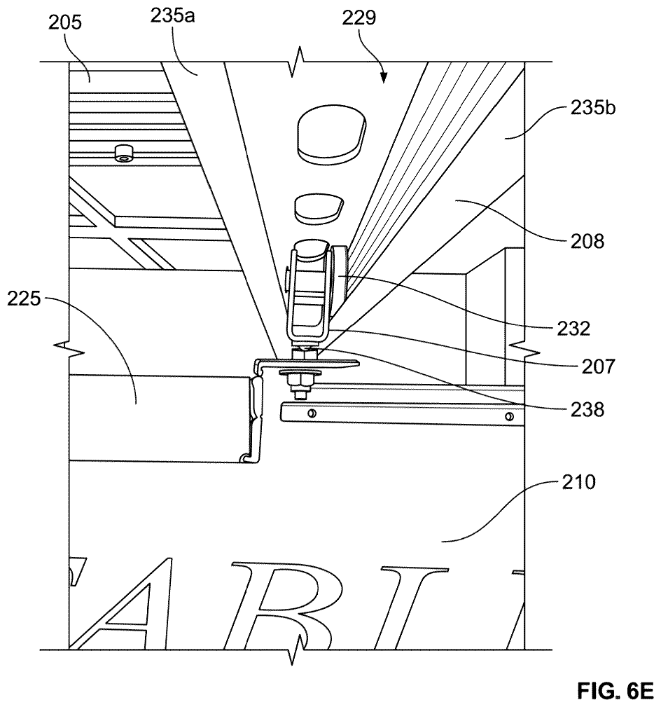

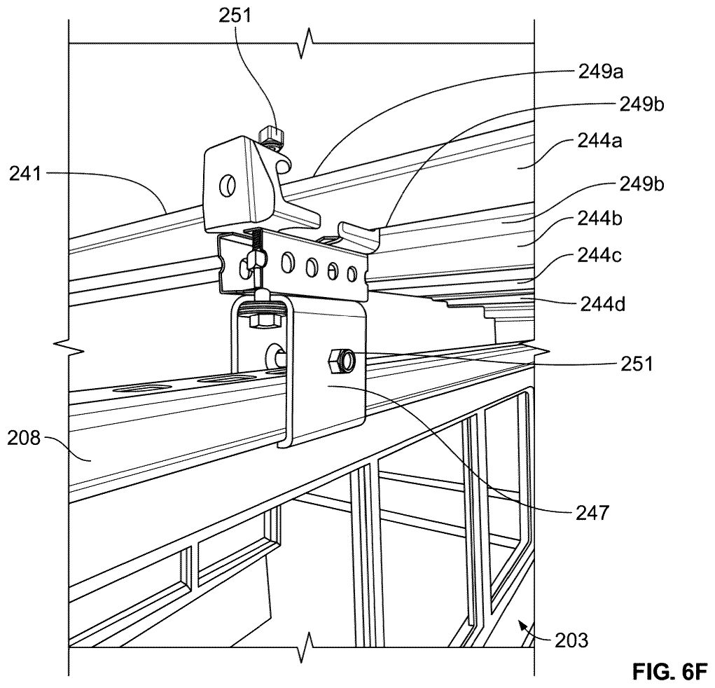

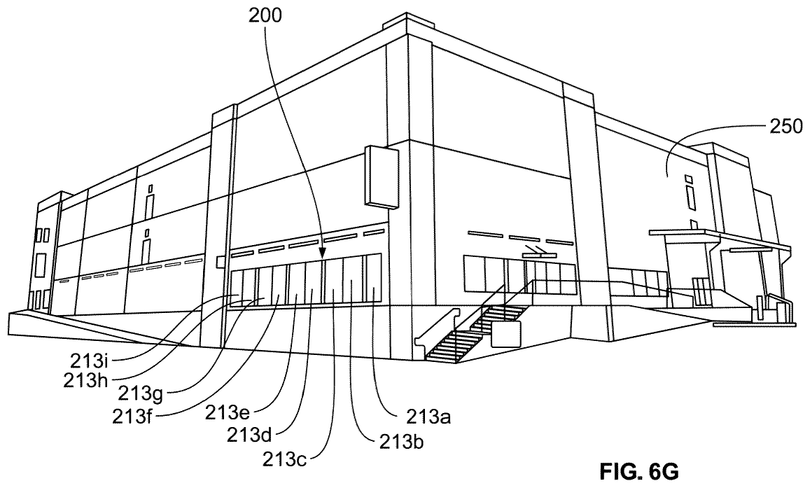

FIGS. 6A-6C illustrate additional examples of a demonstrative model system 200 in accordance with some embodiments. The demonstrative model system 200 may be substantially the same as or include similar features as described above regarding the demonstrative model system 100. As illustrated in FIGS. 6A-6C, the demonstrative model system 200 is configured to operate in a space 203. In some embodiments, the space 203 is defined by one or more structures, such as a floor 204, at least one wall 206a-b, at least one end wall, such as end wall 207, and a barrier 210. The demonstrative model system 200 may include at least one track 208a-b coupled to a portion of the space 203 and the barrier 210.

The space 203, may be any suitable volume, such as a room or storage unit. The space 203 may be fully or partially enclosed with the floor 204, the walls 206a-b, and the end walls 207 similar to a storage unit, as shown in FIG. 6A, the front may be open without a wall, which provides some advantages (e.g. ease of access, open environment, etc.) The space 203 may also have one or more windows disposed within the walls 206a-b so a customer may see the demonstrative model system 200 from outside of the space 203.

The demonstrative model system 200 may include at least one track 208a-b to facilitate movement of the barrier 210 within the space. In some embodiments, the demonstrative model system 200 includes two or more tracks 208a-b to provide better stability. In even further embodiments, the demonstrative model system 200 may include one or more tracks on the wall 206a-b of the space 203 and/or on the floor 204 of the space 203 in addition to or in place of the tracks 208a-b from the ceiling (if present) of the space 203.

The barrier 210 may be a door, partition, wall, sign, curtain, etc. to simulate a far wall of a storage unit. In some embodiments, the barrier 210 may be of a material substantially similar to a storage unit (e.g., metal, such as aluminum, or metal alloy). However, it will be appreciated that the barrier 210 may be of other materials such as plastic, tarp, drywall, wood or wood composite, fabric, glass, etc. In some embodiments, the barrier 110 may also be in the form a light projection (e.g., illuminated screen, hologram, etc.).

As illustrated in FIG. 6A, the barrier 210 is operatively coupled to the tracks. The barrier 210 is configured to move along the tracks 208a-b to demonstrate different sizes of a space 203. In some embodiments, the barrier 210 may include a handle 215 for a user to push or pull the barrier 210 along the tracks 208a-b to change the position of the barrier 210, the handle 215 may be recessed as to be flush with the barrier 210 and may be located on both sides of the barrier 210.

A user of the demonstrative model system 200 may stop the barrier 210 at key measurement intervals corresponding to different storage space sizes. For example, the barrier 210 may be stopped at positions corresponding to a 5 feet by 5 feet, 5 feet by 10 feet, 10 feet by 10 feet, 10 feet by 15 feet, 10 feet by 20 feet, 10 feet by 25 feet, 10 feet by 30 feet, 10 feet by 35 feet, 10 feet by 40 feet, or some other size corresponding to a storage unit size associated with the particular storage center. As described later, the barrier 210 may also be formed of several deployable barriers, each at a fixed position corresponding to one of a plurality of pre-established locations, and selectively deployable as described later.

The demonstrative model system 200 may be installed in a room designed for display and marketing instead of a space 203 similar to a storage unit. For example, windows (and/or doors to the office or from outside of the building may be added to the demonstrative model system 200. The use of windows allows an operator to show the plurality of storage unit sizes without the need to enter the space 203. In some embodiments, accent lights or back lighting within the space 203 may also be used to provide customers with adequate lighting to determine their storage size needs.

The demonstrative model system 200 may include one or more indicia that represent the different storage unit sizes. For example, the indicia may be one or more signs fixed to one of the walls 206a-b, on the floor 204, or hanging from the ceiling 205. The indicia may also be presented on a display 217 fixed to a portion of the space 203, such as the ceiling 205 or fixed to one of the walls 206a-b. In some embodiments, the display 217 may be fixed to the barrier 210 or disposed within a portion of the space 203 (floor, or wall). The display 217 may be located on one or both front and back sides of the barrier 210. In some embodiments, the indicia 255 may be projected onto the barrier 210 (as illustrated in FIG. 6A), the floor 204, or one of the walls 206a-b to indicate the key measurement intervals.

As an example, a plurality of relays may be disposed within the tracks 208a-b and are communicatively coupled to the display 217. The barrier 210 activates at least one of the plurality of relays as the barrier 210 is moved, which sends a signal to the display 217 based on the location of the at least one relay along the tracks 210. In even further embodiments, the relays may provide an input to an automated voice announcement that audibly announces the storage unit size as the barrier 210 passes each of the respective relays.

Although the demonstrative model system 200 has been described as being a fixed width (e.g., a nominal 10 foot width), the demonstrative model system 200 may be configured to change sizes to simulate different storage unit sizes. For example, as illustrated in FIG. 6B, the space 203 facing the customer could start out with dimensions of 10 feet by 30 feet. As the barrier 210 is moved closer, illustrating smaller storage unit sizes, the demonstrative model system could be configured to change the dimensions of the space facing the customer (e.g., from 5 feet by 10 feet to 5 feet by 5 feet). In this example, a portion 219 of the barrier 210 may be configured to fold in through the use of hinges to simulate a smaller space. The demonstrative model system 200 may use a size changing device 222 to simulate the smaller storage unit size throughout the rest of the length of the space 203, as shown in FIG. 6C For example, the size changing device 222 may include a partition configured to extend away from the side wall 206b of the space 203 to the folded portion 219 of the barrier 210 so as to change the dimensions of the space 203. In some embodiments, the size changing device 222 may be curtains configured to extend from the ceiling 205 to simulate the smaller storage unit sizes (e.g., 5 feet by 5 feet), as shown in FIG. 6C.

As illustrated in FIG. 6D, the tracks 208a-b may be coupled to a wall 206a-b of the space 203 and/or hung from beams in the ceiling 205 of the space 203. In some embodiments, a frame 225 is coupled to the barrier 210 and movement mechanisms (discussed in more detail below) on each track 208a-b to stabilize the barrier 210 and prevent the barrier 210 from swinging in the lateral direction. The frame 225 may be coupled to one or more movement mechanisms within each track and the barrier. In some embodiments, the frame 225 includes one or more frame members 227a-b, which provide added stability to the barrier 210. Although two tracks 208a-b are illustrated in FIG. 6D, it will be appreciated that the demonstrative model system 200 may use one or more tracks 208a-b to facilitate movement of the barrier 210 within the space 203.

FIG. 6E illustrates a close up view of a track 208 of a demonstrative model system 200 in accordance with some embodiments. The track 208 defines a void 229 that is sized to receive a movement mechanism 232, such as a wheel, bearing, roller, etc. The track 208 also define a pair of ledges 235a-b configured to fixate the movement mechanism 232 within the void 229 while also allowing the movement mechanism 232 to freely move longitudinally along the track 208. The movement mechanism 232 may be coupled to a first end of a fastener 238, such as a pin. A second end of the fastener 238 is coupled to the barrier 210 so that movement of the movement mechanism 232 moves the barrier 210 from a first position to a second position.

As discussed regarding FIG. 3B, the tracks 208a-b may include indentions 132 so that the barrier 210 stops at each desired key measurement interval. For example, as the barrier 210 is moved from a first position (e.g., 10 feet by 30 feet) to a second position (e.g., 10 feet by 25 feet), the movement of barrier 210 is interrupted by the indention 132 within the tracks 208a-b at the second position, to assist the operator in positioning the barrier 210. When the operator of the demonstrative model system 200 is ready to move the barrier 210 to a third position (e.g., 10 feet by 20 feet) or back to the first position, the operator releases the barrier 210 with a latch or by applying pressure to the barrier to free the barrier 210 from the indention 132.

In even further embodiments, magnets may be used to restrain the barrier 210 at each of the plurality of key measurement intervals. For example, one or more magnets on the barrier 210 may be used to magnetically couple with one or more magnets within the tracks 208a-b at each of the plurality of key measurement intervals. To move the barrier 210, the operator of the demonstrative model system 200 applies pressure to the barrier 210 so that the magnets within the tracks 208a-b and the on the barrier 210 are no longer aligned. Magnets could also be implemented on the floor of the space 203 and configured to couple to magnets on the bottom of the barrier 210. Magnets could further be implemented on the walls 206a-b of the space and configured to couple to magnets on the sides of the barrier 210.

FIG. 6F illustrates a brace 241 of a demonstrative model system 200. The brace 241 may be coupled to one or more beams 244a-e in the ceiling 205. For example, the brace 241 may use a clamp 247 to removably fixate the track 208 to the edges 249a-b of the beams 244 through the use of one or more fasteners 251. Fixation of the brace 241 secures the track 208 within the space 203, allowing the barrier 210 to move along the track 208. Although only one brace 241 is shown, multiple braces 241 may be used at predetermined lengths, such as every 2 feet, 5 feet, 10 feet, or any other suitable distance to provide adequate stability of the tracks 208a-b.

In some embodiments, a pulley, chain or drive system within the tracks 208a-b may be used to mechanically move the barrier 210. For example, an operator (e.g., manager of the facility) of the demonstrative model system 200 could pull a cable attached to the pulley system disposed within the tracks 208a-b to move the barrier 210 instead of having to physically move the barrier 210 by hand. In even further embodiments, the demonstrative model system 200 may include a motor coupled to the pulley system or other similar movement system. The motor may be used to automatically move the barrier 210 in response to a command from an input/output device (e.g., button, switch, remote, etc.). The motor could also be communicatively coupled to a computing device, described in more detail below. The computing device, such as a keypad or a smartphone, may be communicatively coupled to the motor through wired or wireless connection. For example, the computing device could be wirelessly connected to the motor through WI-FI, Bluetooth, RFID, or other similar wireless technology. In some embodiments, the computing device is configured to send a movement command to the motor through an application running on the computing device.

FIG. 6G illustrates a storage facility 250 having another example of a demonstrative model system 200 in accordance with some embodiments. As discussed above, the demonstrative model system 200 may be installed at a storage facility 250. An operator at the storage facility 250 may use the demonstrative model system 200 to easily show a prospective customer the different storage sizes available at the storage facility 250. As discussed above, the demonstrative model system 200 may include one or more windows 213a-i so that a customer may see the demonstrative model system 200 through the windows 213a-i from outside of the space 203.

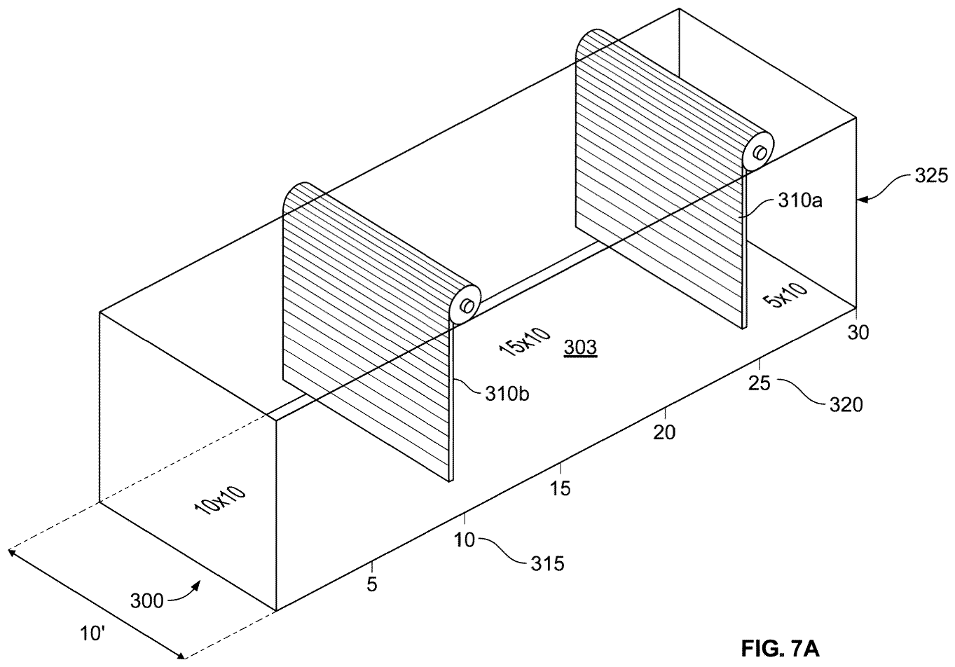

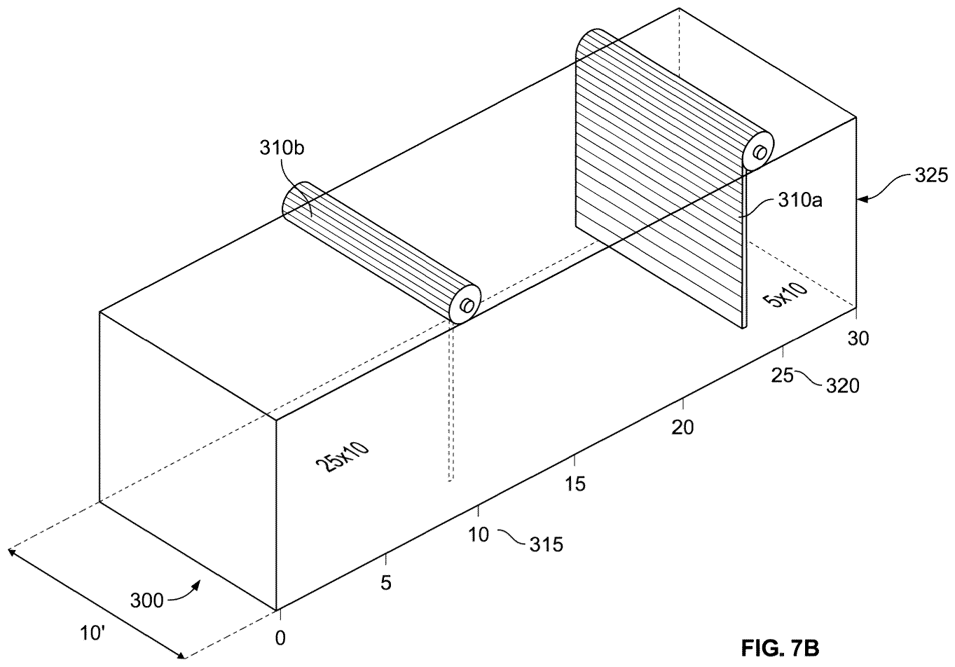

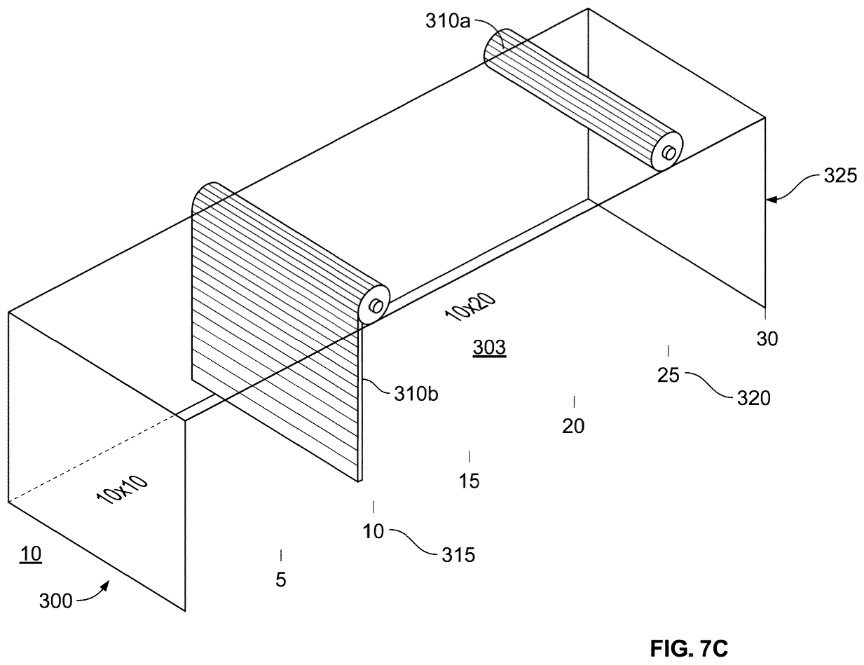

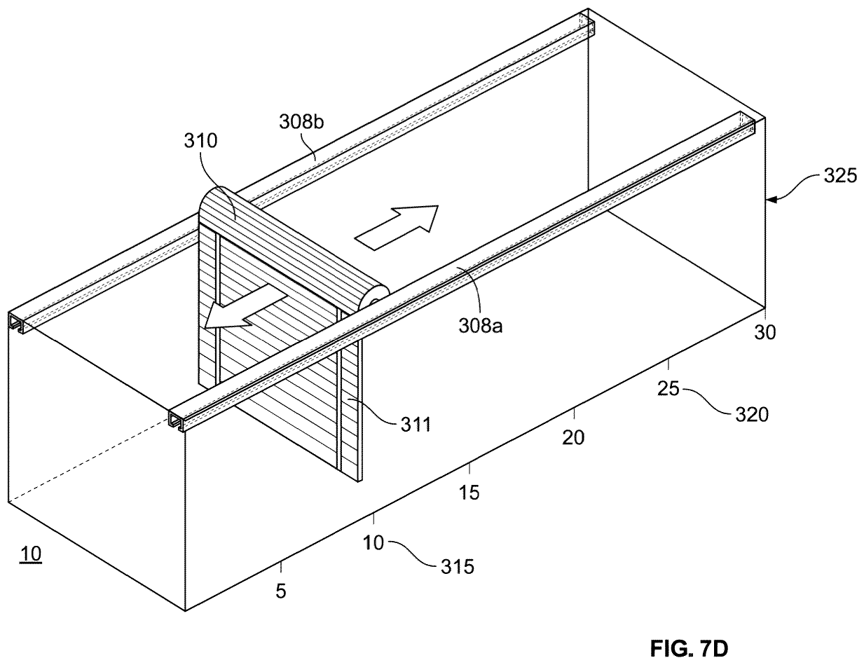

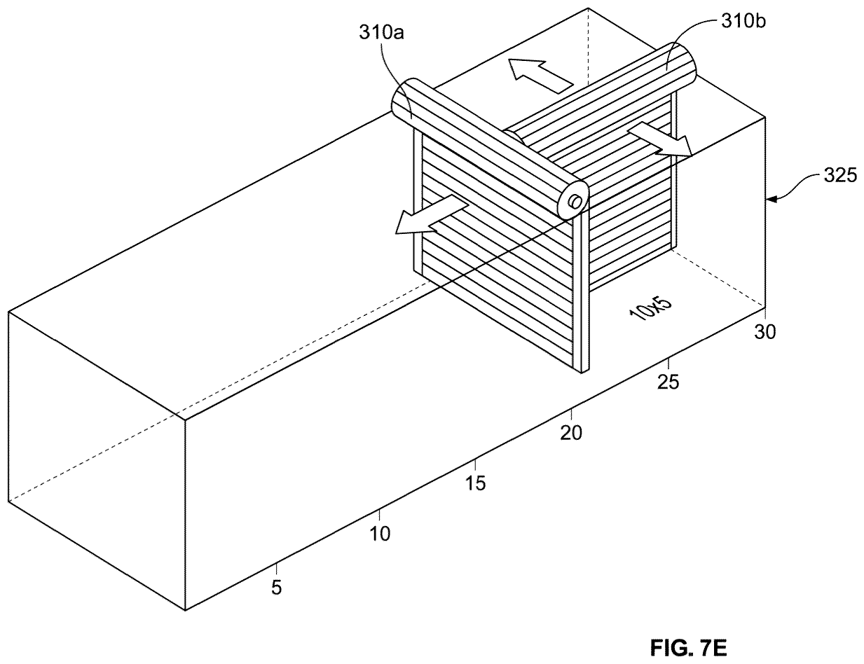

FIGS. 7A-7E illustrate additional variations of a demonstrative model system 300 in accordance with some embodiments. The demonstrative model system 300 may be the same or substantially similar as systems 100 and 200 described above. The demonstrative model system 300 may be configured to change the size of a space 303. The demonstrative model system 300 may include one or pull down walls 310a-b. The pull down walls 310a-b may be hung from the ceiling and configured to be pulled down to change the size of the space 303. As illustrated in FIG. 7A, each of the pull down walls 310a-b may be positioned along the space 303 at the key measurement intervals reflective of the storage unit size available in the facility. For example, in a facility in which 10×30, 10×25, 10×20, 10×15 10×10 and 10×5 units are available, the pull down walls 310a-b may be positioned in a 10×30 space 303 at a 10 foot (KMI) position 315 and 25 foot position 320 from the back 325 of the space 303, or as shown in FIG. 7A the pull down walls 310, may be positioned at key measurement intervals of 10 and 25, thus when extended, a 5×10, 10×10 and 15×10 space may be demonstrated, and when pull down wall 310b is retracted as shown in FIG. 7B, a 25×10 space may be demonstrated. Upon extension of pull down wall 310b and retraction of pull down wall 310a a 20×10 space may be demonstrated as shown in FIG. 7C. Of course additional pull down walls may be fixed at other KMIs, additionally the pull down walls as discussed above with respect to the movable barriers, may be movable along a long a track to two or more KMIs, thus allowing one pull up wall to effectively demonstrate each of the available sizes. In order to demonstrate the entire 10×30 space 303, the two pull down walls 310a-b may be retracted. To demonstrate a 10×25 unit, the pull down wall 310a is engaged, or pulled down from the ceiling. When demonstrating the 10×10 unit, the pull down wall 310b is engaged, or pulled down.

As illustrated in FIG. 7D, the demonstrative model system 300 may include only one pull down wall 310 that is moveable to each of the key measurement intervals (KMIs). The pull down wall 310 may be in the form of a garage door, a screen, a barrier, or other suitable wall, and may represent either end, or either side of the demonstrative model system 300. The pull down wall 310 may extend to form the whole barrier wall, or partially form the barrier. The barrier 310 may form a door 311 within the barrier such that even when deployed, a portion may be retracted similar to the opening of a roll up door.

As illustrated in FIG. 7E, it is also envisioned that a plurality of pull down walls 310a-b may be oriented as to provide representations of two anti-parallel walls. For example, to demonstrate a 10×5 storage unit, the pull down wall 310a located at 10 feet may have a orthogonal pull down wall 310b selectively attached thereto, in which, when engaged, represents a 10 feet side wall bisecting the demonstrated 10×10 space into a 10×5 space. This additional pull down wall 310b may also be fixed or selectively adjustable to demonstrate widths of 8 feet, 6 feet, or 3 feet or any width corresponding to one of the plurality of available units at the facility, or facilities. The demonstrative model system 300, much like described above in addition to selectable depths, may include selectable width, or selectable depths and widths. As with other embodiments described, the pull down walls 310a-b illustrated in FIGS. 7A-7C may be manually or computer controlled.

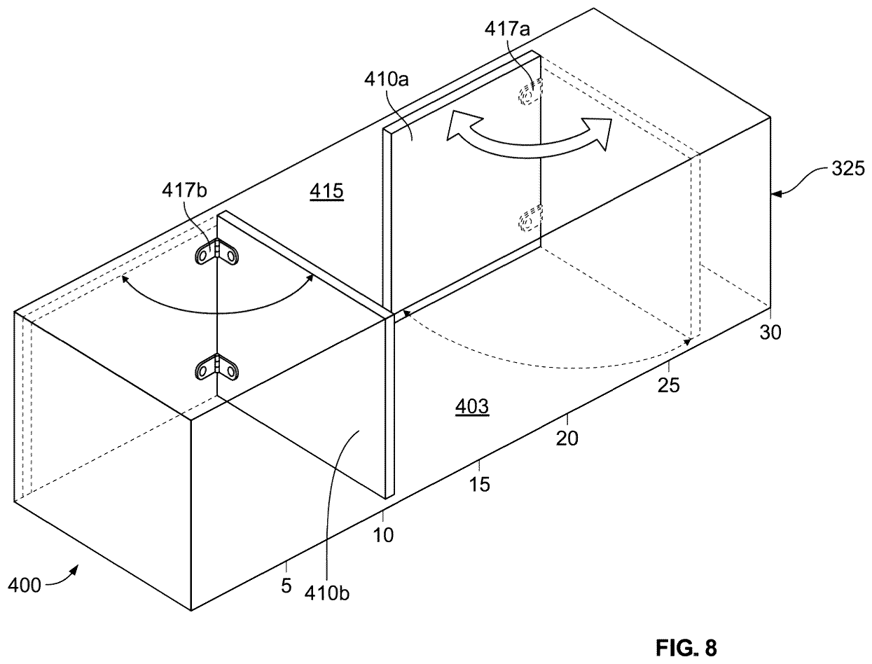

FIG. 8 illustrates another example of demonstrative model system 400 in accordance with some embodiments. The demonstrative model system 400 may be the same or substantially similar as systems 100, 200, and 300 described above. The demonstrative model system 400 may be configured to change the size of a space 403. The demonstrative model system 400 may include one or more hinged walls 410a-b that are used to change the size of the space 403. The hinged walls 410a-b may be operatively coupled to a side wall 415 and configured to be deployed to demonstrate different storage unit sizes, facilitated by a hinge 417a-b coupled to the hinged wall 410a-b and the side wall 415. For example, when demonstrating a 10×30 foot unit, both hinged walls 410a-b are stored against the side wall 415. When demonstrating a 10×20 foot unit, hinged wall 410b is deployed to reduce the size of the space 403, likewise deployed hinged wall 410b also may demonstrate a 10×10 space. When demonstrating a 10×5 or 10×25, hinged wall 410a is deployed. Both 410a and b are deployed to demonstrate a 10×15 foot unit, and each are retracted to show a full 10×30 unit. While not shown in FIG. 8, the hinged walls may be hinged from the ceiling at the KMI and equipped with mechanisms to assist in raising and lowering the hinged walls.

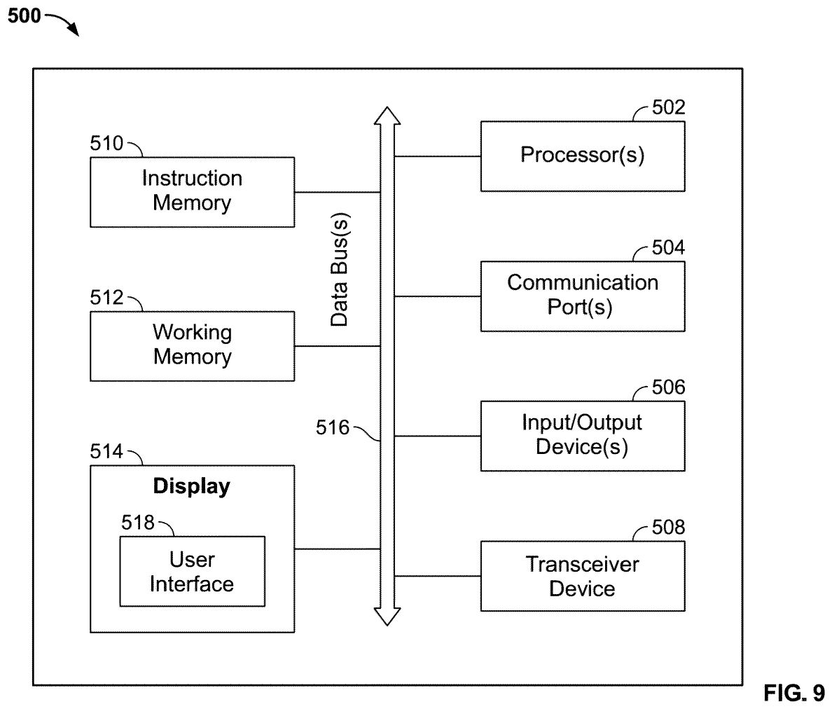

FIG. 9 illustrates a block diagram of an exemplary computing device 500 of a demonstrative model system (e.g., systems 100, 200, 300, and 400) in accordance with some embodiments. The computing device 500 may be employed by a disclosed system or used to execute a disclosed method of the present disclosure. For example, computing device 500 may be a computing device 500 configured to operate a motor and/or a separate controller, such as a smartphone or remote, or configured to wirelessly communicate with computing device 500 communicatively coupled to the motor. It should be understood, however, that other computing device 500 configurations, including distributed and/or cloud-based systems, are possible.

Computing device 500 may include one or more processors 502, one or more communication port(s) 504, one or more input/output devices 506, a transceiver device 508, instruction memory 510, working memory 512, and optionally a display 514, all operatively coupled to one or more data buses 516. Data buses 516 allow for communication among the various devices, processor(s) 502, instruction memory 510, working memory 512, communication port(s) 504, and/or display 514. Data buses 516 may include wired, or wireless, communication channels. Data buses 516 are connected to one or more devices.

Processor(s) 502 may include one or more distinct processors, each having one or more cores. Each of the distinct processors 502 may have the same or different structures. Processor(s) 502 may include one or more central processing units (CPUs), one or more graphics processing units (GPUS), application specific integrated circuits (ASICs), digital signal processors (DSPs), and the like.

Processor(s) 502 may be configured to perform a certain function or operation by executing code, stored on instruction memory 510. For example, processor(s) 502 may be configured to perform one or more of any function, method, or operation disclosed herein.

Communication port(s) 504 may include, for example, a serial port such as a universal asynchronous receiver/transmitter (UART) connection, a Universal Serial Bus (USB) connection, or any other suitable communication port or connection. In some examples, communication port(s) 504 allows for the programming of executable instructions in instruction memory 510. In some examples, communication port(s) 504 allow for the transfer, such as uploading or downloading, of data. In some embodiments, a wired or wireless fieldbus or Modbus protocol may be used.

Input/output devices 506 may include any suitable device that allows for data input or output. For example, input/output devices 506 may include one or more of a keyboard, a touchpad, a mouse, a stylus, a touchscreen, a physical button, a speaker, a microphone, or any other suitable input or output device.

Transceiver device 508 may allow for communication with a network, such as a Wi-Fi network, an Ethernet network, a cellular network, radio signals, Bluetooth, or any other suitable communication network. For example, if operating in a cellular network, transceiver device 508 is configured to allow communications with the cellular network. Processor(s) 502 is operable to receive data from, or send data to, a network via transceiver device 508.

Instruction memory 510 may include an instruction memory 510 that may store instructions that may be accessed (e.g., read) and executed by processor(s) 502. For example, the instruction memory 510 may be a non-transitory, computer-readable storage medium such as a read-only memory (ROM), an electrically erasable programmable read-only memory (EEPROM), flash memory, a removable disk, CD-ROM, any non-volatile memory, or any other suitable memory with instructions stored thereon. For example, the instruction memory 510 may store instructions that, when executed by one or more processors 502, cause one or more processors 502 to perform one or more of the operations of the demonstrative model systems 100, 200, 300, 400.

In addition to instruction memory 510, the computing device 500 may also include a working memory 512. Processor(s) 502 may store data to, and read data from, the working memory 512. For example, processor(s) 502 may store a working set of instructions to the working memory 512, such as instructions loaded from the instruction memory 510. Processor(s) 502 may also use the working memory 512 to store dynamic data created during the operation of computing device 500. The working memory 512 may be a random access memory (RAM) such as a static random access memory (SRAM) or dynamic random access memory (DRAM), or any other suitable memory.

Display 514 may be configured to display user interface 518. User interface 518 may enable user interaction with computing device 500. In some examples, a user may interact with user interface 518 by engaging input/output devices 506. In some examples, display 514 may be a touchscreen, where user interface 518 is displayed on the touchscreen.

The disclosed subject matter may be embodied in the form of methods and apparatus for practicing those methods. The disclosed subject matter may also be embodied in the form of program code embodied in tangible media, such as floppy diskettes, CD-ROMs, DVD-ROMs, Blu-ray disks, hard drives, or any other machine-readable storage medium, wherein, when the program code is loaded into and executed by a machine, such as a computer, the machine becomes an apparatus for practicing the disclosed subject matter. The disclosed subject matter may also be embodied in the form of program code, for example, whether stored in a storage medium, loaded into and/or executed by a machine, or transmitted over some transmission medium, such as over electrical wiring or cabling, through fiber optics, or via electromagnetic radiation, wherein, when the program code is loaded into and executed by a machine, such as a computer, the machine becomes an apparatus for practicing the disclosed subject matter. When implemented on a general-purpose processor, the program code segments combine with the processor to provide a unique device that operates analogously to specific logic circuits.

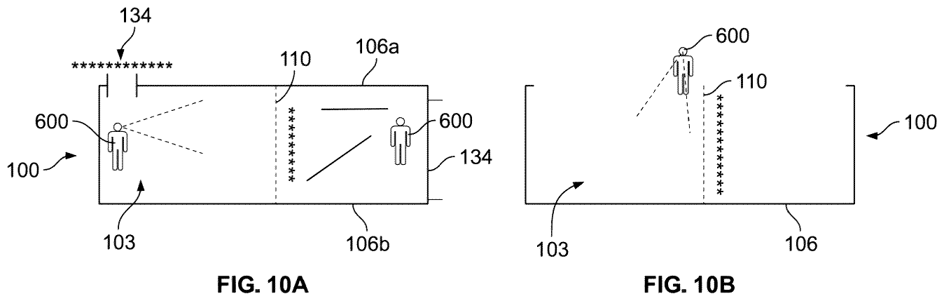

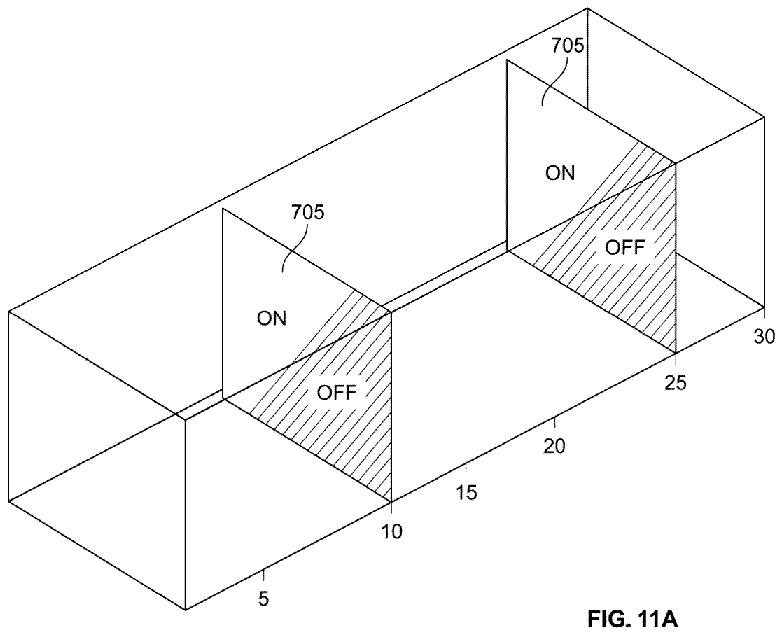

FIG. 10A-10B illustrate various orientations of a demonstrative model system in accordance with some embodiments. The demonstrative model systems disclosed herein (e.g., demonstrative model systems 100, 200, 300, 400) may be configured to present various orientations for the customer 600. For example, FIG. 10A illustrates demonstrative model system 100 configured for the customer 600 to see the barrier 110 move within the space 103 from a head-on point of view (i.e., the barrier 110 moves closer to or further away from the customer 600). However, FIG. 10B illustrates the demonstrative model system 100 configured for the customer 600 to see barrier 110 move within the space 103 from a side point of view (i.e., the barrier 110 moves to the right or left of the customer 600. Other orientations are also contemplated. For example, the demonstrative model systems may be configured such that the customer 600 is situated above or below the space 103.

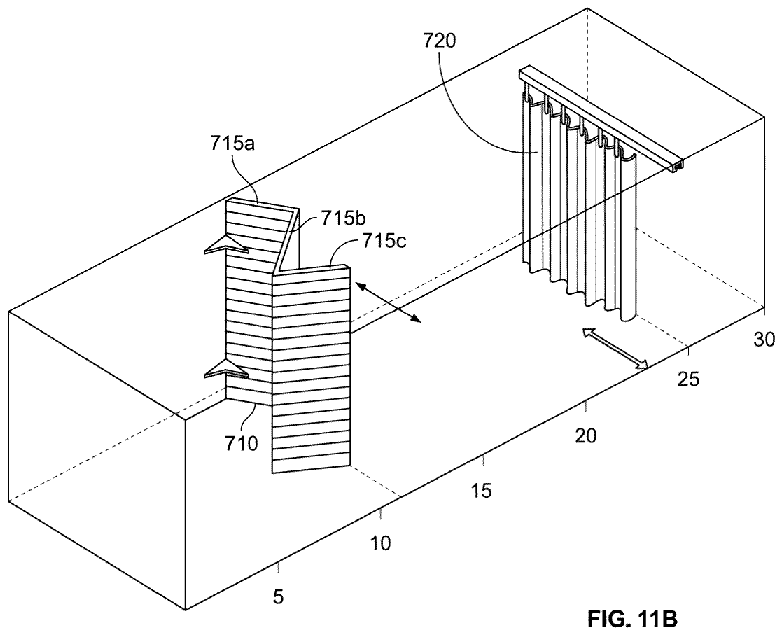

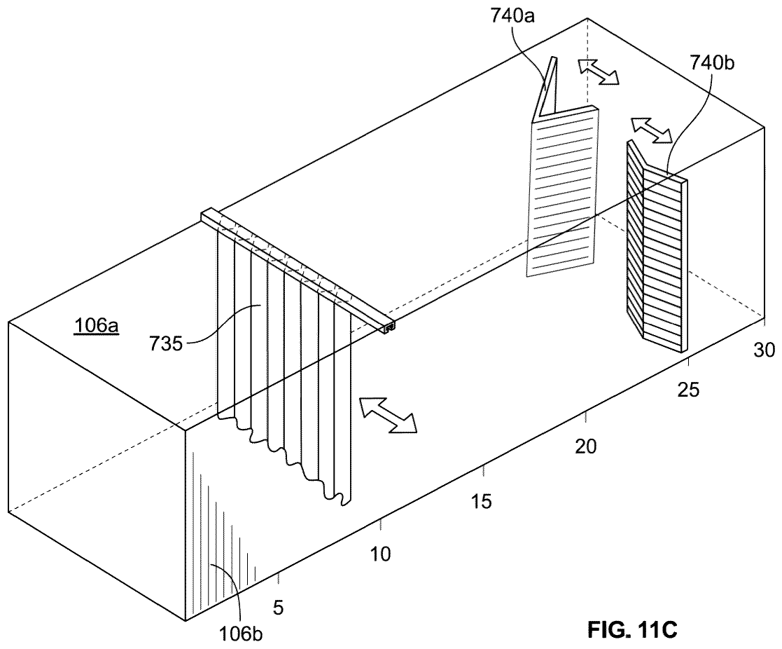

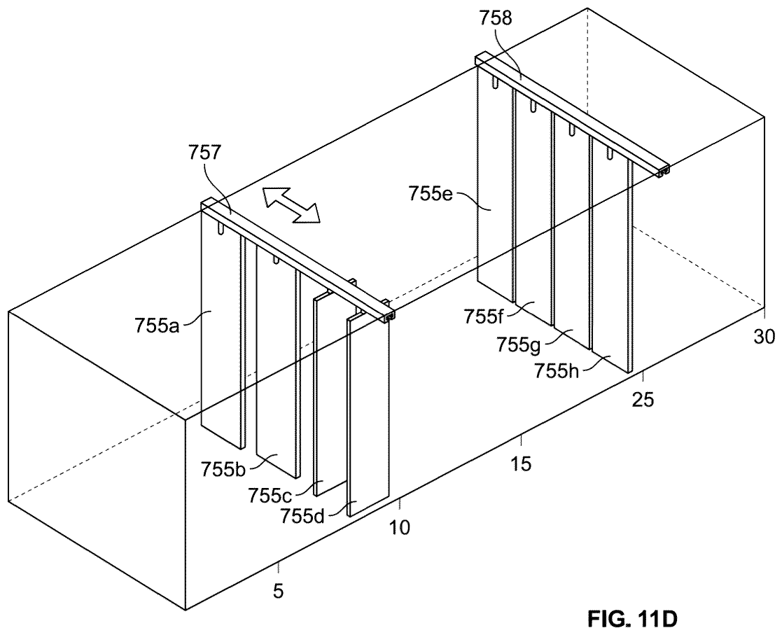

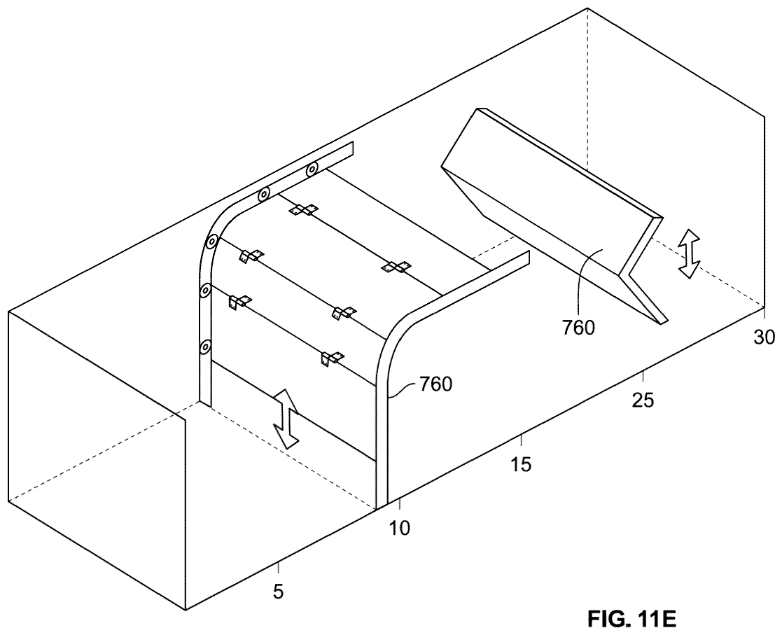

FIGS. 11A-11E illustrate various types of barriers/walls in accordance with some embodiments. Although the barriers (e.g., barriers 110 and 210, pull down walls 310a-b, hinged walls 410a-b, etc.) disclosed herein have been disclosed according to particular embodiments, it will be appreciated that additional variations are also envisioned. For example, the barriers may be one or more smart glass walls 705 situated at the key measurement intervals as illustrated in FIG. 11A. The glass walls 705 may be turned on and off to illustrate different storage unit sizes. As an example, a glass wall 705 disposed at the 20 foot interval of the space may be turned on (i.e., made to be transparent) so that the customer 600 may see through it to another glass wall (or barrier/wall) disposed at another KMI that is turned off (i.e., made to be opaque) to compare multiple storage unit sizes, as described above, deployable walls located at the 10 ft and 25 ft KMI, may be used to represent 10×5, 10×10, 10×15, 10×20, 10×25 and 10×30, in a 10×30 space. In some embodiments, the glass wall 705 may be electrochromic glass. In addition, the barriers may be transparent screens that appear opaque when light is projected upon them.

The barriers may also be one or more accordion barriers 710 as illustrated in FIG. 11B. These accordion barriers 710 may be disposed at each key measurement interval in the space or may be one accordion barrier 710 configured to be moved to each key measurement interval individually. The barriers may also be one or more panel barriers 715a-c as illustrated in FIG. 11B. In some embodiments, the panel barriers 715a-c may include one or more caster assemblies so that the panel barriers 715a-c may be moved to the different key measurement intervals.

As mentioned above, the barrier may also be a curtain 720 as

illustrated in FIG. 11B. As an example, a curtain 720 may be disposed at each key measurement interval and the curtains 720 may be deployed and stored as needed to illustrate the various storage unit sizes. In some embodiments, the curtains 720 may include a cable and pulley system to aid in the deployment and storage of the curtain 720, and as with other variations, the curtain may be computer, electronic or manually controlled.

Further, the barrier, such as the pulldown walls 310a-b, may be a screen as illustrated previously in in FIG. 7A. The screens may be placed at each of the key measurement intervals. As an example, the screen may be wound around a roller and configured to be deployed and stored as needed to illustrate the various storage unit sizes. In some embodiments, the screen may be operated manually. However, the screens may be operated with a motor coupled to a computing device, such as computing device 500.

The barrier may include one or more sliding barriers disposed at each key measurement interval. For example, the sliding barrier may be coupled to tracks and slid along the tracks to deploy and store the sliding barrier. The sliding barriers may be operated as needed at the key measurement intervals to illustrate the different storage unit sizes.

As illustrated in FIG. 11C, the barrier may be a sliding accordion wall 735. The system may include a sliding accordion wall 735 at each of the key measurement intervals. The sliding accordion walls 735 may be operated (e.g., deployed and stored) as needed to illustrate the different storage unit sizes. In some embodiments, the sliding accordion doors 735 are configured to be stored within one of the walls (e.g., walls 106a or 106b) such that the sliding accordion door 735 is hidden from view when stored.

In some embodiments, the barrier may be two bi-fold doors 740a-b as illustrated in FIG. 11C. The system may include two bi-fold doors 740a-b at each key measurement interval. As an example, the bi-fold doors 740a-b at each key measurement interval may be operated to illustrate the different storage unit sizes.

The barrier may be a barrier attached to stanchions. The barrier with stanchions may be placed at each key measurement interval. The barriers maybe moved or rotated as needed to illustrate the different storage unit sizes.

In some embodiments, the barrier may be a gate. As discussed above regarding the hinged walls 410a-b, gates may be placed at each key measurement interval. The gates may be operated about hinge as needed to illustrate the different storage unit sizes.

As illustrated in FIG. 11D, the barrier may include one or more panels 755a-h that are operatively coupled to tracks 757, 758. In some embodiments, a set of panels 755 may be placed at the key measurement intervals. For example, at KMI 10, panels 755a-d on track 757 are positioned. Panels 755a-d are shown being prepared for storage. The panels 755a-d may be moved along the track 757 to deploy and store the panels 755a-d as needed to illustrate the different storage unit sizes. At KMI 25 the panels 755 e-h on track 758 are shown in the deployed position. In other embodiments, one set of panels 755a-d may be configured to travel along the track 757 to each key measurement intervals to illustrate the different storage unit sizes.

In some embodiments, the barrier may be configured as a moving door 760 as illustrated in FIGS. 11E. For example, a moving door 760 may be placed at each of the key measurement interval and operated as necessary to illustrate the different storage unit sizes. In some embodiments, the moving doors 760 may be configured to operate like a garage door. Although the barriers, walls, screens, etc. disclosed herein may be operated manually, it will be appreciated that they may be motor operated. In some embodiments, the motor may be computer controlled through one or more a computing devices, such as computing device 500.

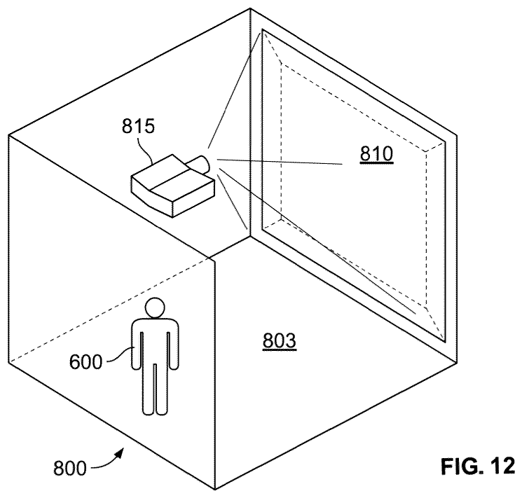

FIG. 12 illustrates a fifth example of a demonstrative model system 800 in accordance with some embodiments. The demonstrative model system 800 may include a space 803 having a screen 810 disposed within the space 803. The demonstrative model system 800 may be configured to project storage units of varying sizes on the screen 810, facilitated by a computing device, such as computing device 500, and a projector 815. For example, a customer 600 may be shown different pictures or simulations of storage units having different sizes. It is contemplated that the pictures or simulations of the storage units include typical examples of what may fit in each size storage unit (e.g., appliances, mattresses, couches, seats, storage boxes, etc.).

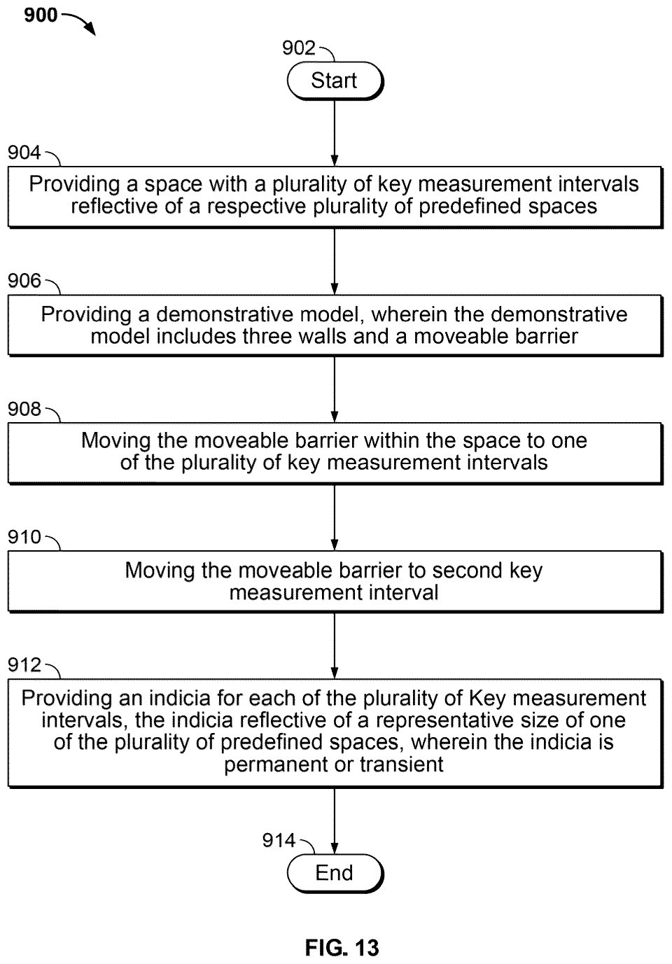

FIG. 13 illustrates a flowchart of an exemplary method 900 of a demonstrative model system in accordance with some embodiments. The method 900 may start at step 902. The method 900 may include step 904, which may comprise providing a space with a plurality of key measurement intervals reflective of a respective plurality of predefined spaces. The method 900 may also include step 906, which may comprise providing a demonstrative model. The demonstrative model may include fixed walls and a moveable barrier. The method 900 may also include step 908, which may comprise moving the moveable barrier within the space to one of the plurality of key measurement intervals. The method 900 may also include step 910, which may comprise moving the moveable barrier to a second key measurement interval, such that the different sized unit may be viewed by the customer. The method 900 may also include step 912, which may comprise providing an indicia for each of the key measurement intervals. The indicia may be reflective of a representative size of the predefined space. The indicia may be permanent or transient. The method 900 may end at step 914. It is envisioned that at least one of the fixed walls bay be represented by a line on the floor or celling.

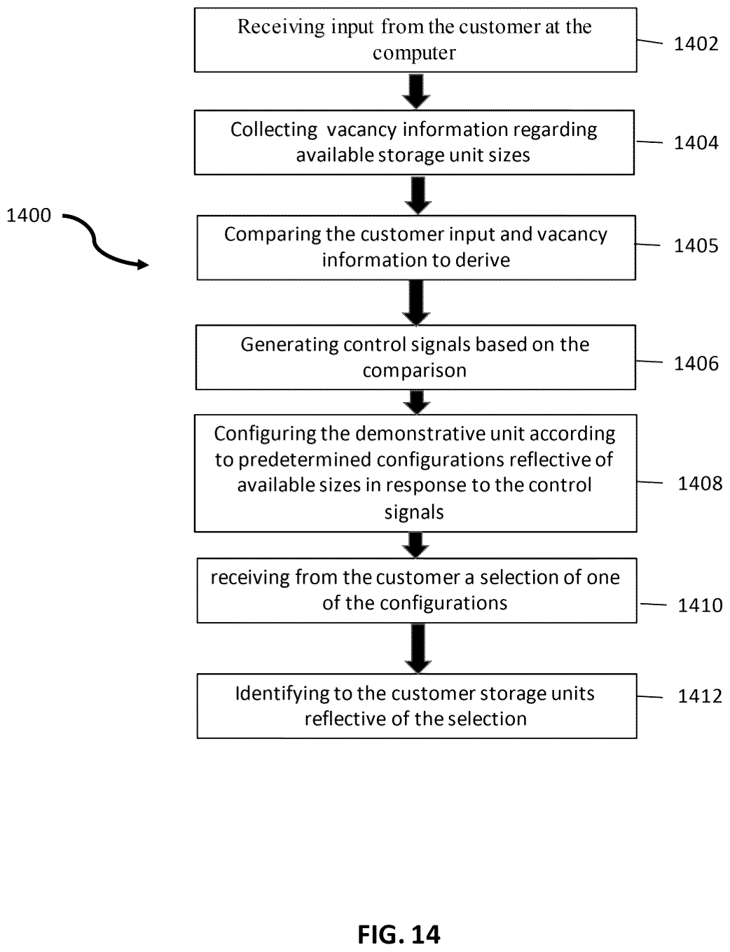

FIG. 14 is a flow chart illustrating an embodiment of a method 1400 for demonstrating available storage unit sizes. The method may utilize several of the embodiments disclosed above including embodiments in which the barrier is movable as well as the embodiments in which the several barriers are selectively deployable. The method of FIG. 14 is practiced in conjunction with a processor such as a personal computer, server or mobile device as described with respect to FIG. 9. A customer provides input to the processor about their storage needs as shown in Block 1402. The input may include information related to the items, rooms, truckloads, volume, weight etc. which the customer needs to store. The information may also include the desired term of storage as well as other characteristic of the rental, such as location within the facility, floor level, access type, conditioned space, start date, cost etc. The information may be input by the customer via a computer, mobile device, or touchscreen. The customer input may also be entered by staff of the facility.

In the method, the processor collects vacancy information regarding the availability of storage units and their respective sizes as shown in Block 1404. This information may be retrieved from memory, manually entered into the processor, or from querying a database. The vacancy information may be periodically collected or collected in real time depending upon the degree of vacancy variability. The processor compares the input with the vacancy information to derive a group or set of units available and nominally capable of meeting the desires of the customer as reflected by the customer's input as shown in Block 1405 and therefrom generates control signals reflective of the sizes of the available units as shown in Block 1406. For example, if the customer input requires at least a 10×15 conditioned first floor unit and the vacancy information includes 10×10, 10×15, 10×20, 10×25 and 10×30 units, with the 10×20 and 10×25 units conditioned, and the 10×15 units and 10×25 units on the first floor. The processor would derive a set of sizes that at least includes the exact match of the 10×25 unit which meets the capacity, floor level and environmental parameters, and preferably would also include the 10×15 unit size which meets the capacity and floor parameters as well as including the 10×20 unit which meets the capacity and environment parameters. The processor would generate control signals that represent each of the 10×15, 10×20 and 10×25 size units.

The demonstrative unit receives the control signals and then configures the demonstrative unit via the control signals to reflect at the available storage unit sizes for consideration by the customer as shown in Block 1408. The configuration may be movement of the movable barrier to one or more predetermined locations to demonstrate the respective units to the customer for example in the manner shown in FIGS. 1, 4, 6A. The configuration may also be the deployment selective deployable barriers to demonstrate the respective available units to the customer for example in the manner shown in FIGS. 7A-7C, 8, 11A-11E. The configuration may also be the combination of movement and deployment of walls (barriers) to demonstrate the respective available unit sizes to the customer for example in the manner shown in FIGS. 6B, 6C, 7D, 7E. In the above example the demonstrative unit would sequentially demonstrate the 10×25 unit to the customer, optionally indicating that the 10×25 unit the matched characteristics of the unit. The demonstrative unit may then after a selected time configure itself via the control signals to demonstrate the 10×15 unit also indicating the respective characteristics and then configure itself to demonstrate the 10×20 unit.

Upon or during the demonstration of the set of available units as determined by the processor, the customer may make a selection of one or more of the configurations reflective of the set of available units, as shown in Block 1410. If no selection is made by the customer, the processor may devise another set of configurations, the additional set including for example less optimal matches such as the 10×10 and the 10×30 units. Alternatively, the processor may provide to the customer incentives for the customer to make a selection.

If a selection is made by the customer, the processor identifies one or more specific storage units reflective of the customers selection as shown in Block 1412. If the customer chose a 10×25 unit on the first floor and conditioned, the processor may provide the locations and number of each of the vacant units meeting the customers preference. For example the processor may identify unit 102, 103 located near the entrance of the facility and units 145, 146 located at the far edge of the facility. The locations of the units in the facility may also be displayed to the customer. The customer may then be directed to complete the rental application for the selected unit. The method illustrated in FIG. 14 may be conducted automatically, with the assistance of the storage facility operator and/or with customer prompts.

Aspects of the disclosed subject matter allow for various implementations, which provide additional advantages. One aspect of the disclosed subject matter is the indication of predefined positions on the floor or wall of the space, the indications may be printed, projected or electronically displayed. The electronic display be also be disposed on the barrier.

Another aspect of the disclosed subject matter is that the barrier may be configured such that its movement may be interrupted at each of the storage sizes by indentations or other mechanisms in the track or movement mechanism.

An additional aspect of the disclosed subject matter is the automatic control of the position of the barrier by user input via a computer in which the barrier may be moved to one of more of the desired positions.

It is also an aspect of the disclosed subject matter that the movable barrier or fourth wall may be used to represent available unit sizes as predetermined based on vacancy at the storage facility, and the position of the movable barrier reflects a respective non common dimension of a respective one of the available unit sizes.

A further aspect of the disclosed subject matter includes that the barrier may include a retractable portion that, when deployed, forms an opaque, transparent, or translucent wall.

Still another aspect of the disclosed subject matter is that the barrier or fourth wall may be a roll up door, a foldable door or an accordion type wall.

Yet another aspect of the disclosed subject matter is that the barrier may be biased to each of the key measurement intervals that represent the available storage unit sizes.

Yet still another aspect of the disclosure subject matter is that the demonstrative model may be implemented with a preexisting storage unit, or may be prescriptively implemented in a showroom or office. Additionally the disclosed subject matter may be implemented at locations remote from the storage units, and may additionally be configured to be mobile which may facilitate off site sales, promotions and advertising.

It should be understood, while the terms “width” and “length” are used to describe the subject matter herein, no distinction is intended other than these terms represent the orthogonal two dimensional sides of a rectangle (i.e. Side A, Side B), whether a particular dimension is a width or is a length is a matter of perspective, or convention. Furthermore, the use of width and length, further represents other common dimensions used to describe the sides of a rectangle such as depth, span, etc.

While different embodiments are described herein, it is envisioned that features described with respect to particular embodiments may also be useful in other embodiments as would be understood by a Person having ordinary skill in the art, and the discussion of a feature with respect to some embodiments and not others should not be interpreted to limit or ascribe such features to only those embodiments.

It may be emphasized that the above-described embodiments, particularly any “preferred” embodiments, are merely possible examples of implementations, set forth for a clear understanding of the principles of the disclosure. Many variations and modifications may be made to the above-described embodiments of the disclosure without departing substantially from the spirit and principles of the disclosure. All such modifications and variations are intended to be included herein within the scope of this disclosure.

While this specification contains many specifics, these should not be construed as limitations on the scope of any disclosures, but rather as descriptions of features that may be specific to a particular embodiment. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments.

Although the disclosed subject matter has been described in terms of exemplary embodiments, it is not limited thereto. Rather, the appended claims should be construed broadly, to include other variants and embodiments of the disclosed subject matter, which may be made by those skilled in the art without departing from the scope and range of equivalents of the disclosed subject matter.

1.-7 (canceled)

8. A storage facility comprising
a plurality of available unit sizes, wherein each of said plurality of available unit sizes have at least one nominal dimension in common;
a demonstrative model system for representing the plurality of available unit sizes;
the demonstrative model system comprising:
a substantially rectangular boundary, wherein one side of the rectangular boundary is the at least one common dimension;
a plurality of walls extending vertically from the rectangular boundary;
a floor perpendicular to and continuous within the rectangular boundary;
at least one selectable wall having the at least one common dimension;
wherein the at least one selectable wall extends between at least one of the plurality of walls and a second side of the rectangular boundary disposed opposite of the respective at least one of the plurality of walls and wherein the at least one selectable wall is locatable at a plurality of predefined positions, such that each position reflects the non common dimension of a respective one of the plurality of available unit sizes.

9. The storage facility of claim 8, wherein the at least one selectable wall unit is supported from overhead, supported by the floor or supported by the plurality of walls.

10. The storage facility of claim 8, wherein the plurality of available unit sizes are predetermined and reconfigurable based on vacancy at the storage facility.

11. The storage facility of claim 8, wherein the at least one selectable wall is a plurality of selectable wall units, each of the plurality of selectable wall units reflecting a respective non common dimension of a respective one of the plurality of available unit sizes.

12. The storage facility of claim 11, wherein the at least one selectable wall includes a retractable portion that, when deployed, forms an opaque, transparent, or translucent wall.

13. A demonstrative model system comprising:
a first wall, a second wall, and a third wall, wherein the first wall and the second wall are parallel and the third wall is perpendicular to the first wall and the second wall;
a fourth wall, extending between the first wall and the second wall, positional along the first wall and the second wall with respect to the third wall;
the first wall, the second wall, the third wall, and the fourth wall defining a selectable space based on one of a plurality of positions of the fourth wall with respect to the third wall, wherein the fourth wall is suspended from overhead, supported by a floor or by the first or second walls;
wherein the selectable space and the respective positions of the fourth wall are predetermined; and,
the fourth wall is biased to each of the plurality of positions.

14. The demonstrative model system of claim 13, wherein the fourth wall has a representative side facing an interior of the selectable space, the representative side having features reflective of an interior wall, an exterior wall, a window, a door, or other building finishes.

15. The demonstrative model system of claim 13, wherein the respective position of the fourth wall at each of the plurality of positions is computer controlled.

16. The demonstrative model system of claim 13, wherein the fourth wall comprises a plurality of walls, each selectively deployable at one of a plurality respective fixed position corresponding to one of the plurality of positions.

17. The demonstrative model system of claim 13, wherein a portion of the fourth wall is vertically retractable.

18. The demonstrative model system of claim 13, wherein the fourth wall is maintained in a vertical position with respect to the floor during movement from one position to another.

19. The demonstrative model system of claim 13, wherein the third wall is positional along the first wall and the second wall wherein and the third wall is suspended from overhead, supported by a floor or by the first or second walls.

20. The demonstrative model system of claim 19, wherein the location of the third wall is computer controlled.

21. The demonstrative model system of claim 19, wherein the third wall is maintained in a vertical position with respect to the floor during movement from one position to another.

22. A method for dividing a space comprising:
providing a horizontal space with a plurality of key measurement intervals reflective of a plurality of predefined spaces;
providing a demonstrative model, wherein the demonstrative model includes at least two fixed vertical walls and a moveable barrier; the at least two fixed walls defining at least two boundary lines of the space and the moveable barrier extending vertically from the horizontal space;
moving the moveable barrier within the space to one of the plurality of key measurement intervals; wherein the moveable barrier and the at least two fixed walls define three sides of one of the plurality of predefined spaces reflected by the respective key measurement interval;
moving the moveable barrier within the horizontal space to a second of the plurality of key measurement intervals, wherein the moveable barrier and the at least two fixed walls define three sides of another of the plurality of predefines spaces reflected by the second key measurement interval; and
providing an indicia for each of the plurality of key measurement intervals, the indicia reflective of a size of the respective ones of the plurality of predefined spaces, wherein the indicia is permanent or transient.

23. The method of claim 22, further comprising a third fixed wall, the third fixed wall perpendicular to one of the at least two fixed walls.

24. The method of claim 22, wherein, the movable barrier is biased to each of the key measurement intervals.

25-31. (canceled)

32. A method of demonstrating a plurality of storage unit sizes, wherein each of the plurality of storage units have a respective length and share a common width, comprising:
obtaining the respective length dimensions for each of the plurality of storage units
providing a rectangular area, the rectangular area having a first dimension greater than or equal to each of the respective length dimensions and a common width dimension;
selectively dividing the rectangular area to represent at least one of a set of rectangles, each sharing at least the common width dimension corresponding in size with a respective one of the plurality of storage unit sizes;
moving a barrier to each of the different length dimensions represented in the set of rectangles to demonstrate the respective storage unit size.

33. The method of claim 32, further comprising:
determining for each length dimension whether there is an available storage unit sharing the respective length dimension, wherein the set of rectangles includes rectangles in which the respective length dimension has a corresponding available storage unit.

34. The method of claim 33, wherein, each length dimension without a corresponding available storage unit is removed from the set of rectangles, prior to moving the barrier.

35-39. (canceled)
